(19) United States
(12) Patent Application Publication
(10) Pub. No.: US 2026/0169044 A1
(43) Pub. Date: Jun. 18, 2026

(54) METHOD OF AND DEVICE FOR CALCULATING FAR-FIELD

(71) Applicant: SAMSUNG ELECTRONICS CO., LTD., Suwon-si (KR)

(72) Inventors: Koji MURATA, Yokohama (JP); Yuka Ebata, Yokohama (JP); Kwanghee Lee, Suwon-si (KR)

(73) Assignee: SAMSUNG ELECTRONICS CO., LTD., Suwon-si (KR)

(21) Appl. No.: 19/413,716

(22) Filed: Dec. 9, 2025

(30) Foreign Application Priority Data
Dec. 12, 2024 (JP) 2024-217647

(51) Int. Cl. G01R 29/08

(52) U.S. Cl. CPC G01R 29/0871

(57) ABSTRACT

A method of determining a far-field includes determining, by a computer using an electromagnetic field analysis method, a near-field of each of a plurality of cells in a target structure, determining, by the computer using a filter function, a factor for each of the plurality of cells required for determining a far-field of the target structure, and determining, by the computer using the near-field of each of the plurality of cells and the factor for each of the plurality of cells, the far-field of the target structure.

### CROSS-REFERENCE TO RELATED APPLICATIONS

This application is based on and claims priority to Japan Patent Application No. 2024-217647, filed on Dec. 12, 2024, in the Japan Patent Office, the disclosure of which is incorporated by reference herein in its entirety.

### BACKGROUND

The present disclosure relates to a method and a device for accelerating far-field calculation in optical or electromagnetic-field analysis simulation.

A far-field distribution according to reflection or transmission when light is incident on a target structure depends on a plurality of structural portions (hereinafter also referred to as “cells”) included in the target structure. For each of the cells, a near-field is determined using an electromagnetic-field analysis method or an optical simulation method, and the far-field may then be obtained by using an equivalence theorem from the near-field distribution obtained by filtering the determined near-field with an elliptic or Gaussian function. For example, a case may be considered in which the cells of the target structure are periodically arranged, and the far-field produced by the reflected light when light having circular diffusion is incident on the cells is determined.

References D1 and D2 propose speeding up far-field calculation by thinning near-fields. However, there is an issue that the near-fields have to be thinned.

Reference D3 proposes a method of obtaining a far-field for a radiation field. However, there is an issue in that far-fields are not obtained from reflection fields and transmission fields produced by a periodic structure.

### REFERENCES

D1: JP 2024-059345A
D2: JP 2023-156195A
D3: JP 2008-209123A

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Additional aspects will be set forth in part in the description which follows and, in part, will be apparent from the description, or may be learned by practice of the presented embodiments.

According to an aspect of an example embodiment, a method of determining a far-field may include determining, by a computer using an electromagnetic field analysis method, a near-field of each of a plurality of cells in a target structure, determining, by the computer using a filter function, a factor for each of the plurality of cells required for determining a far-field of the target structure, and determining, by the computer using the near-field of each of the plurality of cells and the factor for each of the plurality of cells, the far-field of the target structure.

According to an aspect of an example embodiment, an electronic device may include memory storing instructions, and a processor, where the instructions, when executed by the processor, cause the electronic device to determine, by using an electromagnetic field analysis method, a near-field of each of a plurality of cells in a target structure, determine, by using a filter function, a factor for each of the plurality of cells required for determining a far-field of the target structure, and determine, based on the near-field of each of the plurality of cells and the factor for each of the plurality of cells, the far-field of the target structure.

According to an aspect of an example embodiment, a non-transitory computer-readable storage medium may store instructions that, when executed by at least one processor, cause the at least one processor to determine, by using an electromagnetic field analysis method, a near-field of each of a plurality of cells in a target structure, determine, by using a filter function, a factor for each of the plurality of cells required for determining a far-field of the target structure and determine, based on the near-field of each of the plurality of cells and the factor for each of the plurality of cells, the far-field of the target structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating an observation point (θ, Φ) of a far field in a target structure having periodically arranged cells;

FIG. 2 is a diagram illustrating an example of cells included in a target structure;

FIG. 3 is a diagram illustrating a state in which cells having a near field that generates an equivalent current for one period are replicated and a circular filter is applied;

FIG. 4 is a diagram illustrating an example of a determined far-field distribution;

FIG. 5 is a schematic diagram illustrating a far-field calculation system according to an embodiment;

FIG. 6 is a flowchart illustrating a far-field calculation processing procedure when an instruction for far-field calculation according to a comparative example is executed by a computer;

FIG. 7 is a diagram illustrating an example of a relationship between a function F(x, y) and Lx and Ly;

FIG. 8 is a flowchart illustrating a far-field calculation processing procedure when an instruction for far-field calculation according to Embodiment 1 is executed by a computer;

FIG. 9 is a diagram illustrating an elliptic filter used for comparison between a comparative example and Embodiment 1;

FIG. 10 is a diagram illustrating a far-field calculation time in the comparative example and Embodiment 1 when the elliptic filter of FIG. 9 is applied;

FIG. 11 is a diagram illustrating a Gaussian filter used for comparison between the comparative example and Embodiment 1;

FIG. 12 is a diagram illustrating a far-field calculation time in the comparative example and Embodiment 1 when the Gaussian filter of FIG. 11 is applied;

FIG. 13 is a diagram illustrating a Gaussian filter used for comparison between the comparative example and Embodiment 1;

FIG. 14 is a diagram illustrating a far-field calculation result in a comparative example when the Gaussian filter of FIG. 13 is applied.

FIG. 15 is a diagram illustrating a far-field calculation result in Embodiment 1 when the Gaussian filter of FIG. 13 is applied.

FIG. 16 is a diagram illustrating an interpolation method;

FIG. 17 is a diagram illustrating an example in which near-fields contributing to a far-field calculation do not have perfect periodicity;

FIG. 18 is a diagram illustrating an example of a one-dimensional filter function;

FIG. 19 is a flowchart illustrating a far-field calculation processing procedure when an instruction for far-field calculation according to Embodiment 3 is executed by a computer;

FIG. 20 is a diagram illustrating an example in which some cells include defects;

FIG. 21 is a flowchart illustrating a far-field calculation processing procedure when an instruction for far-field calculation according to Embodiment 5 is executed by a computer;

FIG. 22A is a diagram illustrating an example of a plurality of cells in which cells having a filter function of 1 are shown in white and cells having a filter function of 0 are shown in black;

FIG. 22B is a diagram illustrating rectangular areas extracted from (a) of FIG. 22;

FIG. 22C\ is a diagram illustrating a case in which an outer portion of a circle has a value between 0 and 1;

FIG. 23 is a diagram illustrating a specific method of the rectangular areas extracted in FIG. 22B;

FIG. 24 is a flowchart illustrating a far-field calculation processing procedure when an instruction for far-field calculation according to Embodiment 6 is executed by a computer;

FIGS. 25A, 25B, 25C, and 25D are diagrams illustrating examples of rectangular extraction methods;

FIG. 26 is a block diagram of a system according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

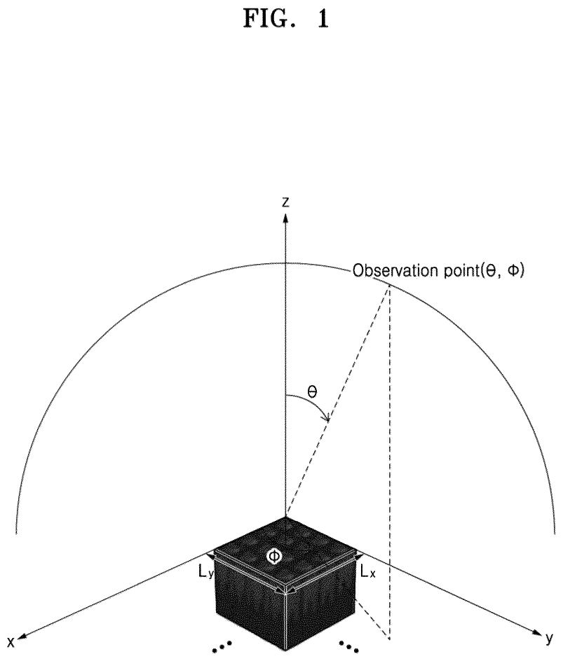

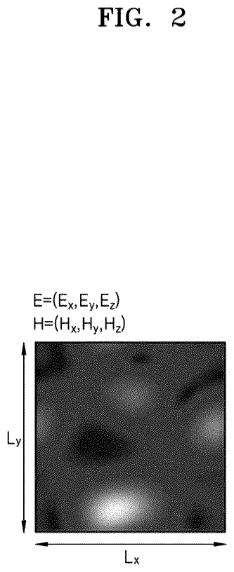

FIG. 1 is a diagram illustrating a far-field observation point (θ, Φ) of a target structure in which cells are periodically arranged. FIG. 2 is a diagram illustrating an example of cells included in the target structure.

Referring to FIGS. 1 and 2, for one period of the target structure, an electromagnetic-field analysis method such as a finite-difference time-domain (FDTD) method or a rigorous coupled-wave analysis (RCWA) method, or an optical simulation method, is applied together with periodic boundary conditions to obtain a steady electromagnetic field on a top surface of the target structure. A steady-state electric field E and a magnetic field H on the top surface of the structure may be expressed as follows.

$$E = ( {E}_{x} , {E}_{y} , {E}_{z} ) , H = ( {H}_{x} , {H}_{y} , {H}_{z} ) \qquad ( 1 )$$

Next, an equivalent current on the top surface of the target structure for simulation is obtained based on these near-fields. An electric current density J and magnetic current density M on the target surface may be expressed as follows.

$$J = \hat{n} \times H , M = - \hat{n} \times E \qquad ( 2 )$$

Here, n\hat{ } is a unit normal vector of a surface where the near-field and the equivalent current exist.

In the examples of FIGS. 1 and 2, because the near-field and the equivalent current exist on the top surface of the target structure, these may be expressed as follows.

$$\hat{n} = ( 1 , 0 , 0 ) , J = ( - {H}_{y} , {H}_{x} , 0 ) , M = ( {E}_{{y}^{′}} - {E}_{{x}^{′}} 0 ) \qquad ( 3 )$$

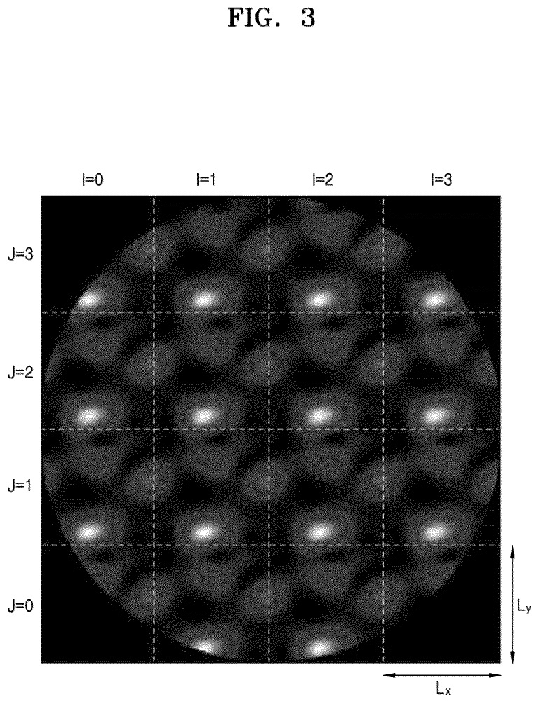

FIG. 3 is a diagram illustrating cells having near-fields that generate equivalent currents for one period, replicated and circularly filtered.

FIG. 3 represents the near-fields of the entire circularly filtered reflected light. Using the equivalence theorem, the far-field distribution “FarField(θ, Φ)” may be expressed as the following Equation (4).

$$FarField ( θ , ϕ ) = \frac{{k}^{2}}{8 π {\vert {E}_{inc} \vert}^{2}} ( {\vert \sqrt{{ε}_{r}} {L}_{ϕ} + {N}_{θ} \vert}^{2} + {\vert \sqrt{{ε}_{r}} {L}_{θ} - {N}_{ϕ} \vert}^{2} ) \qquad ( 4 )$$

In Equation (4), N_{θ}(θ, Φ), N_{Φ}(θ, Φ), L_{θ}(θ, Φ), and L_{Φ}(θ, Φ) may be expressed by Equations (5) to (8), respectively.

$${N}_{θ} ( θ , ϕ ) = \int \int F ( x , y ) {\sum }_{I = 0}^{{N}_{x}} {\sum }_{J = 0}^{{N}_{y}} ( {J}_{x} cos θ cos ϕ + {J}_{y} cos θ sin ϕ - {J}_{z} sin θ ) {e}^{- ik [ ( x + {IL}_{y} ) sin θ cos ϕ + ( y + {JL}_{x} ) sin θ sin ϕ + z cos θ ] + i ( {k}_{x} {IL}_{x} + {k}_{y} {JL}_{y} )} dxdy \qquad ( 5 )$$

$${N}_{ϕ} ( θ , ϕ ) = \int \int F ( x , y ) {\sum }_{I = 0}^{{N}_{x}} {\sum }_{J = 0}^{{N}_{y}} ( - {J}_{x} sin ϕ + {J}_{y} cos ϕ ) {e}^{- ik [ ( x + {IL}_{y} ) sin θ cos ϕ + ( y + {JL}_{x} ) sin θ sin ϕ + z cos θ ] + i ( {k}_{x} {IL}_{x} + {k}_{y} {JL}_{y} )} dxdy \qquad ( 6 )$$

$${L}_{θ} ( θ , ϕ ) = \int \int F ( x , y ) {\sum }_{I = 0}^{{N}_{x}} {\sum }_{J = 0}^{{N}_{y}} ( {M}_{x} cos θ cos ϕ + {M}_{y} cos θ sin ϕ - {M}_{z} sin θ ) {e}^{- ik [ ( x + {IL}_{y} ) sin θ cos ϕ + ( y + {JL}_{x} ) sin θ sin ϕ + z cos θ ] + i ( {k}_{x} {IL}_{x} + {k}_{y} {JL}_{y} )} dxdy \qquad ( 7 )$$

$${L}_{ϕ} ( θ , ϕ ) = \int \int F ( x , y ) {\sum }_{I = 0}^{{N}_{x}} {\sum }_{J = 0}^{{N}_{y}} ( - {M}_{x} sin ϕ + {M}_{y} cos ϕ ) {e}^{- ik [ ( x + {IL}_{y} ) sin θ cos ϕ + ( y + {JL}_{x} ) sin θ sin ϕ + z cos θ ] + i ( {k}_{x} {IL}_{x} + {k}_{y} {JL}_{y} )} dxdy \qquad ( 8 )$$

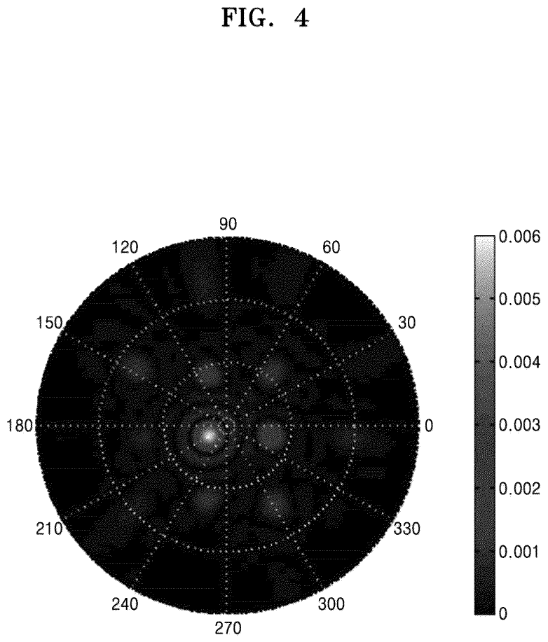

FIG. 4 is a diagram illustrating an example of a determined far-field distribution.

Referring to FIGS. 1 to 4, x and y are coordinates of the target surface where the near-field and the equivalent current exist, and z is a vertical coordinate of that surface. The near field and the equivalent current are functions of coordinates x and y. The function F(x, y) represents a range of light reflection or transmission (for example, an elliptic or a Gaussian function), and Lx and Ly are widths of one period of the target structure in x and y directions. I and J are region numbers of the near field of the replicated cell in x and y directions, and Nx and Ny are numbers of replications of the near field in x and y directions. θ is a polar angle (an angle formed with a z-axis), Φ is an azimuthal angle (an angle formed with an x-axis on an x-y plane), k is a wave vector of light, kx and ky are x- and y-components of a wave vector of incident light, εr is a relative permittivity with respect to vacuum on a surface where the near field exists, and E_{inc} is a complex amplitude of an incident electric field.

In related art, near-field data obtained from optical simulations such as FDTD or RCWA are electromagnetic-field data arranged in a mesh form, and double integrals in the relevant equations are numerically solved. Therefore, when performing a far-field calculation by using the above equations, six nested loops of θ, Φ, I, J, x, and y may be required, and the calculation may take time accordingly. The calculation time may be shortened by methods such as thinning the near-field arrays normally used for the calculation or limiting ranges of θ and Φ to be determined by predicting a directivity to some extent. However, in large-scale far-field calculations where the range of light reflection or transmission is wide, the number of loops of I and J for cell replication may become very large. For the loops of I and J for replicating the cells, when thinning of array data such as that used for a one-cycle near-field is performed, macroscopic properties of the entire near-field may disappear, and thus it may be difficult to increase the calculation speed by the conventional method described above.

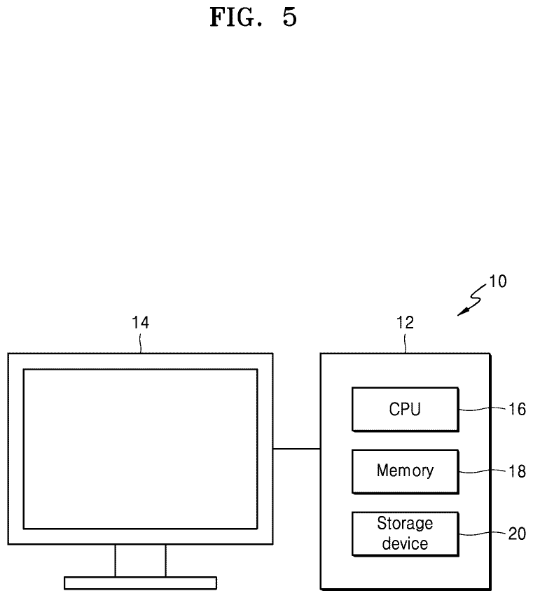

FIG. 5 is a schematic diagram illustrating a far-field calculation system 10 according to an embodiment.

Referring to FIG. 5, the far-field calculation system 10 may include a computer 12 and a display 14. The computer 12 may include a central processing unit (CPU) 16, memory 18, and a storage device 20. The storage device 20 may store a far-field calculation instruction. The computer 12 may execute the far-field calculation instruction stored in the storage device 20 using the CPU 16 and memory 18, etc. Calculation results are output to the display 14 via a cable, and the display 14 may visually display the calculation results. A far-field calculation instruction may be stored in a storage device 20 of the computer 12 for a general purpose to execute far-field calculation processing procedure. However, the computer 12 may be configured with dedicated hardware for the far-field calculation. In this case, the computer 12 may function as a far-field calculation device.

### Comparative Example

First, the processing procedure when the far-field calculation instruction according to the comparative example is executed on the computer 12 is described. As described above, a far-field distribution due to reflection or transmission when light is incident on a target structure may be determined by using an equivalence theorem (Equation (4) described above) from a near-field distribution determined by filtering the near-field determined by an electromagnetic-field analysis method or an optical simulation method with an elliptic or Gaussian function for each of a plurality of cells included in the target structure.

The double integral in Equation (5) may be discretized into mesh coordinates xi and yj taken on an x-y plane, and by substituting an Equation of an equivalent current, the expression may be represented as Equation (9) below.

$${N}_{θ} ( θ , ϕ ) = {\sum }_{I} {\sum }_{J} {\sum }_{i} {\sum }_{j} F ( {x}_{i} + {IL}_{x} , {y}_{j} {JL}_{y} ) \{ - {H}_{y} ( {x}_{i} , {y}_{i} ) cos θ cos ϕ + {H}_{x} ( {x}_{i} , {y}_{j} ) cos θ sin ϕ \} {e}^{- {ikx}_{i} sin θ cos ϕ} {e}^{- {iky}_{j} sin θ sin ϕ} {e}^{- {iK}_{x} {IL}_{x} - {iK}_{y} {JL}_{y} - ikz cos θ} Δ {x}_{i} Δ {y}_{j} \qquad ( 9 )$$

In Equation (9), the subscripts i and j of xi and yj indicate the i-th and j-th coordinates of the mesh coordinates. Δxi, Δyj represent mesh widths corresponding thereto. The exponent of an exponential function includes an imaginary unit i=√(−1) which does not operate with the subscript i of the coordinate and is thereby always distinguished from the subscript i. In addition, for ease of understanding, Kx and Ky are expressed as Kx=k sin θ cos Φ−kx and Ky=k sin θ sin Φ−ky. For definitions of other variables, reference may be made to the explanation of the related art described above. When Equation (9) is transformed into Equation (10), a factor (F_{CellCopy}) related to cell replication may be expressed as a formula such as Equation (11). Hereinafter, this factor is referred to as a “cell replication factor.”

$${N}_{θ} ( θ , ϕ ) = {e}^{- ikz cos θ} {\sum }_{i} {\sum }_{j} \{ - {H}_{y} ( {x}_{i} , {y}_{j} ) cos θ cos ϕ + {H}_{x} ( {x}_{i} , {y}_{j} ) cos θ sin ϕ \} {e}^{- {ikx}_{i} sin θ cos ϕ} {e}^{- {iky}_{j} sin θ sin ϕ} Δ {x}_{i} Δ {y}_{j} {F}_{CellCopy} \qquad ( 10 )$$

$${F}_{CellCopy} = {\sum }_{I} {\sum }_{J} F ( {x}_{i} + {IL}_{x} , {y}_{j} + {JL}_{y} ) {e}^{- {iK}_{x} {IL}_{x}} {e}^{- {iK}_{y} {JL}_{y}} \qquad ( 11 )$$

Here, a case may be considered in which the cell structure as shown in FIG. 2 is periodically arranged, and when light having circular diffusion is incident thereon, a far-field formed by reflected light is determined at high speed. Equations for performing this calculation may be expressed as follows.

$$FarField ( θ , ϕ ) = \frac{{k}^{2}}{8 π {\vert {E}_{inc} \vert}^{2}} ( {\vert \sqrt{{ε}_{r}} {L}_{ϕ} + {N}_{θ} \vert}^{2} + {\vert \sqrt{{ε}_{r}} {L}_{θ} - {N}_{ϕ} \vert}^{2} ) \qquad ( 12 )$$

$${N}_{θ} ( θ , ϕ ) = {e}^{- ikz cos θ} {\sum }_{i} {\sum }_{j} \{ - {H}_{y} ( {x}_{i} , {y}_{j} ) cos θ cos ϕ + {H}_{x} ( {x}_{i} , {y}_{j} ) cos θ sin ϕ \} {e}^{- {ikx}_{i} sin θ cos ϕ} {e}^{- {iky}_{j} sin θ sin ϕ} Δ {x}_{i} Δ {y}_{j} {F}_{CellCopy} \qquad ( 13 )$$

$${N}_{ϕ} ( θ , ϕ ) = {e}^{- ikz cos θ} {\sum }_{i} {\sum }_{J} \{ {H}_{y} ( {x}_{i} , {y}_{j} ) sin ϕ + {H}_{x} ( {x}_{i} , {y}_{j} ) cos ϕ \} {e}^{- {ikx}_{i} sin θ cos ϕ} {e}^{- {iky}_{j} sin θ sin ϕ} Δ {x}_{i} Δ {y}_{j} {F}_{CellCopy} \qquad ( 14 )$$

$${L}_{θ} ( θ , ϕ ) = {e}^{- ikz cos θ} {\sum }_{i} {\sum }_{j} \{ {E}_{y} ( {x}_{i} , {y}_{j} ) cos θ cos ϕ - {E}_{x} ( {x}_{i} , {y}_{j} ) cos θ sin ϕ \} {e}^{- {ikx}_{i} sin θ cos ϕ} {e}^{- {iky}_{j} sin θ sin ϕ} Δ {x}_{i} Δ {y}_{j} {F}_{CellCopy} \qquad ( 15 )$$

$${L}_{ϕ} ( θ , ϕ ) = {e}^{- ikz cos θ} {\sum }_{i} {\sum }_{j} \{ - {E}_{y} ( {x}_{i} , {y}_{j} ) sin ϕ - {E}_{x} ( {x}_{i} , {y}_{j} ) cos ϕ \} {e}^{- {ikx}_{i} sin θ cos ϕ} {e}^{- {iky}_{j} sin θ sin ϕ} Δ {x}_{i} Δ {y}_{j} {F}_{CellCopy} \qquad ( 16 )$$

$${F}_{CellCopy} ( θ , ϕ , {x}_{i} , {y}_{j} ) = {\sum }_{I = 0}^{{N}_{x} - 1} {\sum }_{J = 0}^{{N}_{y} - 1} F ( {x}_{i} + {IL}_{x} , {y}_{j} + {JL}_{y} ) {e}^{- {iK}_{x} {IL}_{x}} {e}^{- {iK}_{y} {JL}_{y}} \qquad ( 17 )$$

Equations (13) to (16) are obtained by applying a modification to separate the cell replication factor to Equations (5) to (8) of the equivalence theorem described in the background. First, a near-field electromagnetic-field on a top surface of the target structure obtained by an FDTD method or an RCWA method may be determined by substituting the field into equations (13) to (16). The cell replication factor F_{CellCopy} may be expressed as Equation 17.

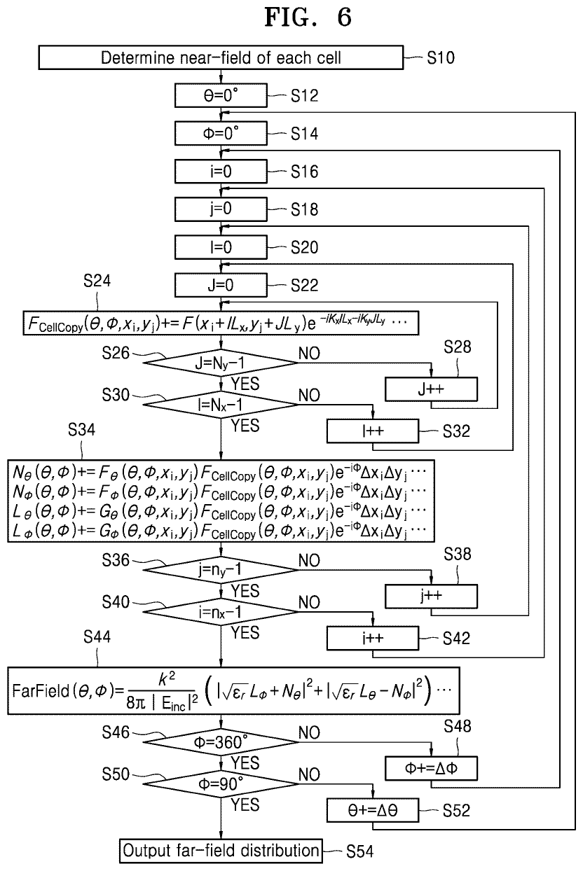

FIG. 6 is a flowchart illustrating far-field calculation processing procedure performed when the far-field calculation instruction according to the comparative example is executed by the computer 12. Hereinafter, “a+=b” means “a=a+b” in Fortran or C language, which sets a+b as a new value for variable a. Also, “a++” is identical to “a+=1”, therefore, “a++” means setting a+1 as a new value for variable a.

Referring to FIG. 6, the computer 12 may determine a near-field of each of a plurality of cells included in a target structure using an electromagnetic-field analysis method such as the FDTD method or the RCWA method (operation S10). Additionally, an electromagnetic-field analysis method other than the FDTD method and RCWA method may be used.

The computer 12 may set initial values of θ, Φ, i, j, I, and J to 0 (operations S12, S14, S16, S18, S20, and S22). The computer 12 may determine the cell replication factor using Equation (11) (operation S24). In this way, in the comparative example, the computer 12 may determine the cell replication factor for each of the plurality of cells included in the target structure using a filter function including an elliptic filter, a Gaussian filter, or the like.

When the cell replication factor is determined, the computer 12 may determine whether N_{y}−1 is equal to J (operation S26). If N_{y}−1 is not equal to J (“NO” in operation S26), the computer 12 may increment J (operation S28) and return to operation S24. If N_{y}−1 is equal to J (“YES” in operation S26), the computer 12 may determine whether Nₓ−1 is equal to I (operation S30), and if not (“NO” in operation S30), may increment I (operation S32) and returns to operation S22.

If Nₓ−1 is equal to I (“YES” in operation S30), the computer 12 may determine each factor of N_{θ}, N_{β}, L_{θ}, and L_{Φ} required for determining the far-field by using Equations (13) to (16) described above (operation S34). Hereinafter, Nθ, NΦ, Lθ, and LΦ may be collectively referred to as a “second factor.” In addition, in operation S34, the terms on right-hand sides of Nθ and NΦ may be respectively set as Fθ and FΦ, the terms on right-hand sides of Lθ and LΦ may be respectively set as Gθ and GΦ, and an exponential part of an exponential function may be set as iΦ.

When operation S34 is ended, the computer 12 may determine whether n_{y}−1 is equal to j (operation S36), and if not (“NO” of operation S36), may increment j (operation S38) and may return to operation S20. If n_{y}−1 is equal to j (“YES” in operation S36), the computer 12 may determine whether nₓ−1 is equal to i (operation S40), and if not (“NO” in operation S40), may increment i (operation S42) and may return to operation S18.

If nₓ−1 is equal to I (“YES” in operation S40), the computer 12 may determine the far field by using Equation (4) (operation S44). When the far-field is determined, the computer 12 may determine whether Φ is equal to 360° (operation S46). If Φ is not equal to 360° (“NO” of operation S46), the computer 12 may set Φ as a new value obtained by adding a certain angle ΔΦ to Φ (operation S48) and return to operation S16.

If Φ is equal to 360° (“YES” in operation S46), the computer 12 may determine the far field by using Equation (4) (operation S44). When the far-field is determined, the computer 12 may determine whether 0 is equal to 90° (operation S50). If θ is not equal to 90° (“NO” of operation S50), the computer 12 may set a new θ by adding a certain angle Δθ to θ (operation S52), and may return to operation S14.

If θ is equal to 90° (“YES” in operation S50), the computer 12 may output a determined far-field distribution (operation S54). Specifically, the computer 12 may display the determined far-field distribution as an image on the display 14. Additionally, the computer 12 may transmit the determined far-field distribution to another device, for example, a server or another computer connected to the computer 12 via a network, such that the server or another computer may output the determined far-field distribution.

In Equations (13) to (16), the near-field of each of the plurality of cells determined in operation S10 and the cell replication factor of each of the plurality of cells determined in operation S24 may be used to determine the second factor consisting of Nθ, NΦ, Lθ, and LΦ. Therefore, in the comparative example, the computer 12 may determine the far-field of the target structure using the near-field and the cell replication factor of each of the plurality of cells.

### Embodiment 1

Next, a processing procedure when the far-field calculation instruction for Embodiment 1 is executed on the computer 12 will be described. In the comparative example, because Equations (5) to (8) require a six-loop calculation, a far-field calculation time may increase when a range in which light is reflected or transmitted is wide, that is, when a cell replication number is large. For this reason, the far-field calculation instruction for Embodiment 1 may be executed by the computer 12 to determine factors necessary for determining the far field for each of a plurality of cells by using a transform function obtained by the analytic Fourier transform of the filter function.

Specifically, when considering an integral as follows, the integral may be expressed as Equation 1-1 below by using a Fourier transform F˜(Kx, Ky) of the function F(x, y) through a substitution integral.

$$\int {\int }_{- ∞}^{+ ∞} F ( {x}_{i} + x , {y}_{j} + y ) {e}^{- i ( {K}_{x} x + {K}_{y} y )} dxdy = \int {\int }_{- ∞}^{+ ∞} F ( {x}^{′} , {y}^{′} ) {e}^{- i [ {K}_{x} ( {x}^{′} - {x}_{i} ) + {K}_{y} ( {y}^{′} - {y}_{j} )} {dx}^{′} {dy}^{′} = {e}^{+ i ( {K}_{x} {x}_{i} + {K}_{y} {y}_{j} )} \int {\int }_{- ∞}^{+ ∞} F ( {x}^{′} , {y}^{′} ) {e}^{- i [ {K}_{x} {x}^{′} + {K}_{y} {y}^{′}} {dx}^{′} {dy}^{′} = {e}^{+ i ( {K}_{x} {x}_{i} + {K}_{y} {y}_{i} )} \tilde{F} ( {K}_{x} , {K}_{y} ) \qquad ( 1 - 1 )$$

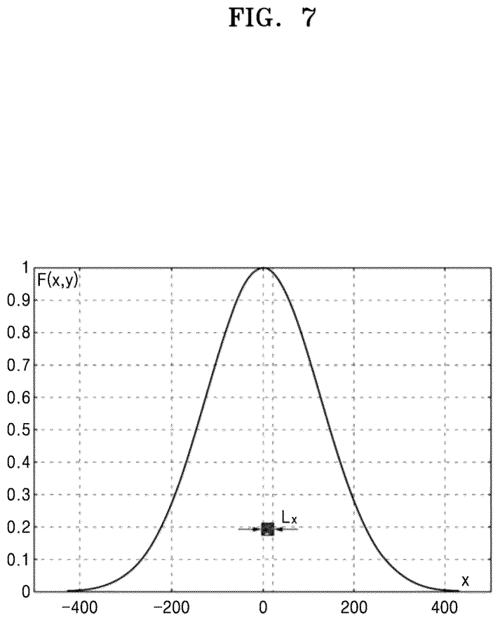

FIG. 7 is a diagram illustrating an example of a relationship between the function F(x, y) and Lx and Ly. Referring to FIG. 7, when the function F(x, y) converges to zero at both ends of a domain and Lx and Ly are sufficiently smaller than a width of the function, the left-hand side of Equation (1-1) may be approximated by a following equation.

$$\int {\int }_{- ∞}^{- ∞} F ( {x}_{i} + x , {y}_{j} + y ) {e}^{- i ( {K}_{x} x + {K}_{y} y )} dxdy ≅ {\sum }_{I = - ∞}^{+ ∞} {\sum }_{J = - ∞}^{+ ∞} F ( {x}_{i} + {IL}_{x} , {y}_{j} + {JL}_{y} ) {e}^{- {iK}_{x} {IL}_{x}} {e}^{- {iK}_{y} {JL}_{y}} {L}_{x} {L}_{y} \qquad ( 1 - 2 )$$

Therefore, from Equations (1-1) and (1-2), a cell replication factor may be expressed as follows under the conditions described above.

$${F}_{CellCopy} ≅ \frac{1}{{L}_{x} {L}_{y}} {e}^{+ i ( {K}_{{x}^{x} i} + {K}_{y} {y}_{j} )} \tilde{F} ( {K}_{x} , {K}_{y} ) \qquad ( 1 - 3 )$$

F(Kₓ, K_{y}) in Equation (1-3) is a Fourier transform of the filter function F(x, y). For example, a case may be considered in which the filter function is an elliptic filter expressed by Equation (1-4).

$$F ( x , y ) = \{ \begin{matrix}1 & ( \frac{{x}^{2}}{{a}^{2}} + \frac{{y}^{2}}{{b}^{2}} \leq 1 ) \\ 0 & ( \frac{{x}^{2}}{{a}^{2}} + \frac{{y}^{2}}{{b}^{2}} > 1 )\end{matrix} \qquad ( 1 - 4 )$$

The Fourier transform may be solved analytically and expressed as in Equation (1-5) below. (J₁(x) in the Equation is a Bessel function of the first kind.)

$$F ( {K}_{x} , {K}_{y} ) = 2 π ab \frac{{J}_{1} ( \sqrt{{a}^{2} {K}_{x}^{2} + {b}^{2} {K}_{y}^{2}} )}{\sqrt{{a}^{2} {K}_{x}^{2} + {b}^{2} {K}_{y}^{2}}} \qquad ( 1 - 5 )$$

In this way, in a case where the filter function is an equation that may be analytically Fourier-transformed, Equation (1-3) may be determined by directly implementing the equation of the analytic Fourier transform in an instruction form for operating the hardware.

Thus, in Embodiment 1, the cell replication factor may be determined by using Equation (1-1) employing a Fourier transform instead of Equation (17) employing a double loop corresponding to a conventional method. The function of performing the Fourier transform of the filter function in Equation (1-1) may be prepared as a pair of the filter function and its Fourier transform. For example, in the case of a circular filter function, because the analytic Fourier transform of a circle becomes a Bessel function of the first kind, a function that returns a value of the Bessel function of the first kind by using a radius of the circle as a parameter may be implemented, and Equation (1-1) may be determined by using this function. By substituting the left-side values of Equations (13) to (16) and Equation (1-1) into Equation (1-3), a far-field in the direction represented by (θ, Φ) may be determined. Because the analytic Fourier transform used in Equation (1-1) is sufficiently faster than Equation (16) using the double loop, the 6-loop of θ, Φ, I, J, x, and y required for the conventional entire far-field calculation may be reduced to a 4-loop of θ, Φ, x, and y, so that calculation speed may be improved.

Furthermore, as another effect, because discontinuity of the function value at a boundary of an analytical domain for the filter function disappears, noise caused thereby may also be eliminated. Here, although transformation and approximation are performed for Equation (5), Equations (6), (7), and (8) may also use identical transformation and approximation.

In addition, when the function F(x, y) is constant, the cell replication factor may be determined by using a geometric series as follows.

$$\begin{matrix}{F}_{CellCopy} & = {\sum }_{I} {\sum }_{J} {e}^{- {iK}_{x} {IL}_{x}} {e}^{- {iK}_{y} {JL}_{y}} \\ & = {\sum }_{I} {e}^{- {iK}_{x} {IL}_{x}} {\sum }_{J} {e}^{- {iK}_{y} {JL}_{y}} \\ & = S ( 1 , {e}^{- {iK}_{x} {L}_{x}} , {N}_{x} ) S ( 1 , {e}^{- {iK}_{y} {L}_{y}} , {N}_{y} )\end{matrix} \qquad ( 1 - 6 )$$

$$S ( a , r , n ) = \{ \begin{matrix}a \frac{1 - {r}^{n}}{1 - r} & ( r \neq 1 ) \\ na & ( r = 1 )\end{matrix} \qquad ( 1 - 7 )$$

By using Equations (1-6) and (1-7), the double integral may become an exact solution of the geometric series, such that the calculation speed may be improved. The present disclosure may also improve the calculation speed by extracting a region in which the filter function F(x, y) is constant and applying Equations (1-6) and (1-7) to that region.

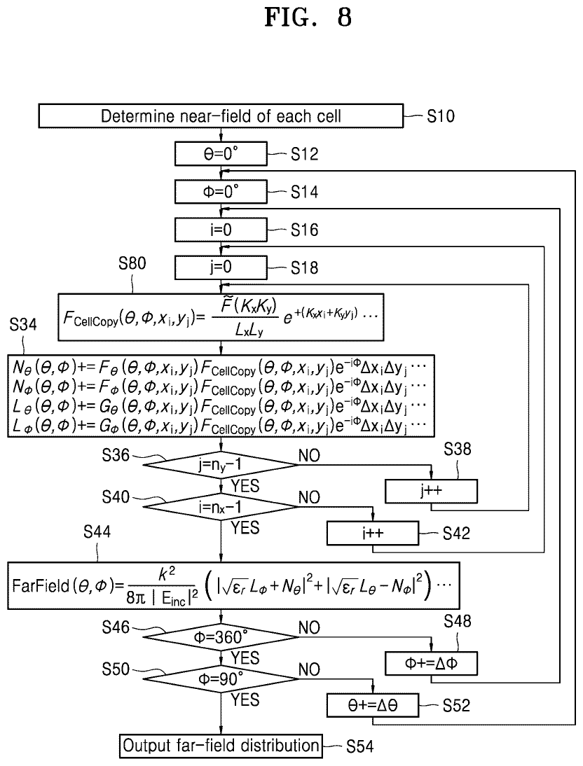

FIG. 8 is a flowchart illustrating a far-field calculation processing procedure when the far-field calculation instruction for Embodiment 1 is executed by the computer 12. Hereinafter, identical reference symbols are given for the same operations as the above-described flowchart, and descriptions thereof are omitted.

Referring to FIG. 8, in Embodiment 1, the computer 12 may execute operation S80 instead of operations S20, S22, S24, S26, S28, S30, and S32 of FIG. 6 in the comparative example. That is, in Embodiment 1, the computer 12 may determine the cell replication factor for each of the plurality of cells by using the transform function obtained by the analytic Fourier transform of the filter function including the elliptic filter, the Gaussian filter, or the like. Operation S10, in which the computer 12 may determine the near-field of each of the plurality of cells included in the target structure by using the electromagnetic-field analysis method, and operations S34 to S54, in which the computer 12 may determine the far-field of the target structure by using the near-field of each of the plurality of cells and the cell replication factor, are identical to those of the comparative example.

Equation (1-2) using the analytic Fourier transform may be capable of high-speed calculation sufficiently faster than Equation (16) using the double loop, and the calculation speed may be improved by reducing the six nested loops of θ, Φ, I, J, x, and y required for the entire far-field calculation to four nested loops of θ, Φ, x, and y.

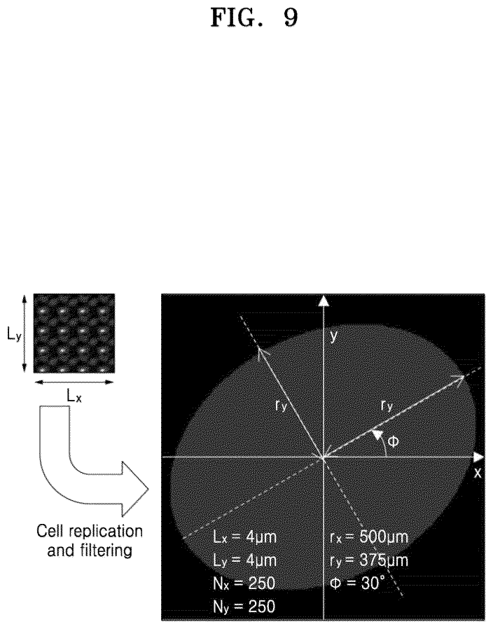

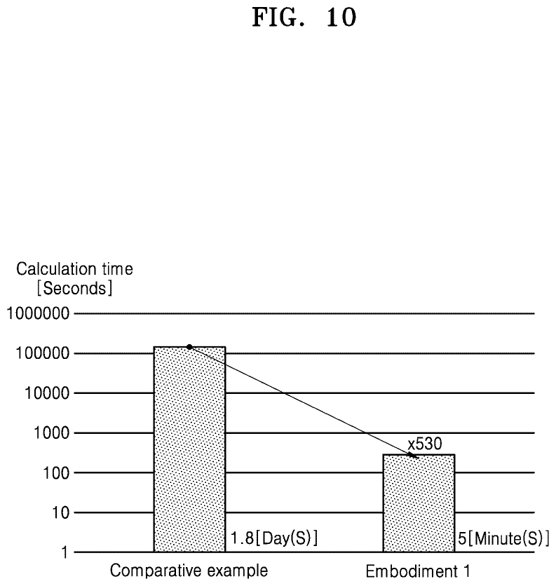

FIGS. 9 and 10 are diagrams illustrating effects according to Embodiment 1. FIG. 9 is a diagram illustrating an elliptic filter used for comparison between the comparative example and Embodiment 1. Referring to FIG. 9, in the elliptic filter, a near-field having a width of Lx=Ly=4 μm is replicated 250 times in the x and y directions, respectively, and an ellipse having a major axis of 500 μm and a minor axis of 375 μm is rotated 30° from the x-axis to the y-axis.

FIG. 10 is a diagram illustrating far-field calculation times in the comparative example and Embodiment 1 when the elliptic filter illustrated in FIG. 9 is applied. Referring to FIG. 10, when using this elliptic filter, the time taken for the far-field calculation in the comparative example is 155,500 seconds. In Embodiment 1, the time taken for far-field calculation is 293 seconds. In this way, by executing Equation (1-2) using the analytic Fourier transform instead of Equation (16) using the double loop, the calculation speed of the far-field may be improved by about 530 times.

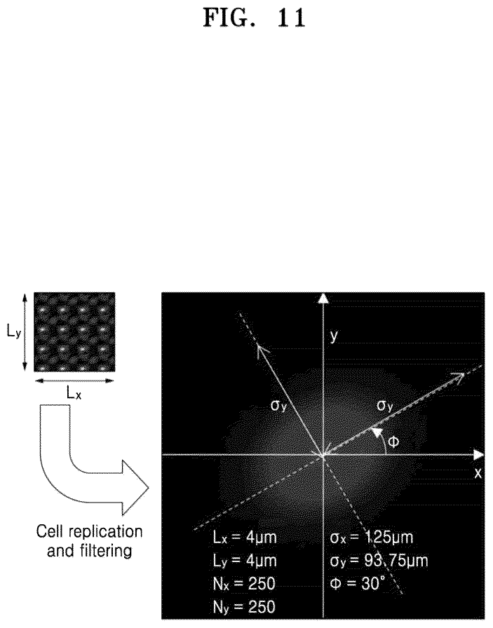

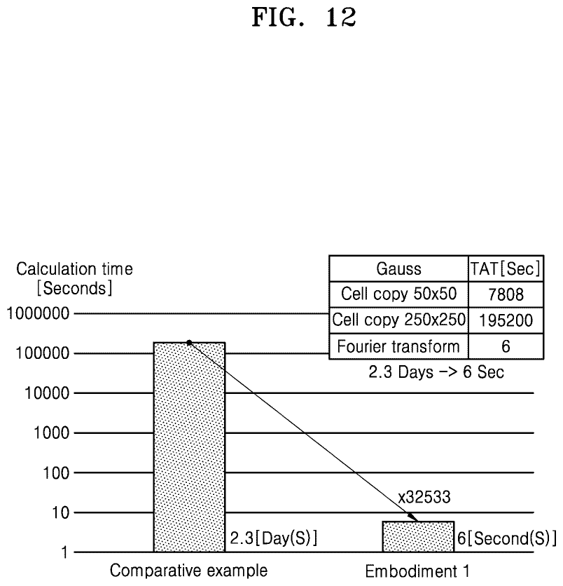

FIGS. 11 and 12 are diagrams also illustrating effects according to Embodiment 1. FIG. 11 is a diagram illustrating a Gaussian filter used for comparison between the comparative example and Embodiment 1. Referring to FIG. 11, in this Gaussian filter, a near-field having a width of Lx=Ly=4 μm is replicated 250 times in the x and y directions, respectively, and a Gaussian function with a standard deviation of 125 μm and 93.75 μm in the x and y directions is rotated 30° from the x-axis to the y-axis.

FIG. 12 is a diagram illustrating far-field calculation times in the comparative example and Embodiment 1 when the Gaussian filter illustrated in FIG. 11 is applied. Referring to FIG. 12, in the comparative example using this Gaussian filter, the time taken for the far-field calculation is 195,200 seconds. In Embodiment 1, the time taken for the far-field calculation is 6 seconds. In this way, by executing Equation 1-3 using the analytic Fourier transform instead of Equation 17 using the double loop, the calculation speed of the far-field may be improved by approximately 32,533 times.

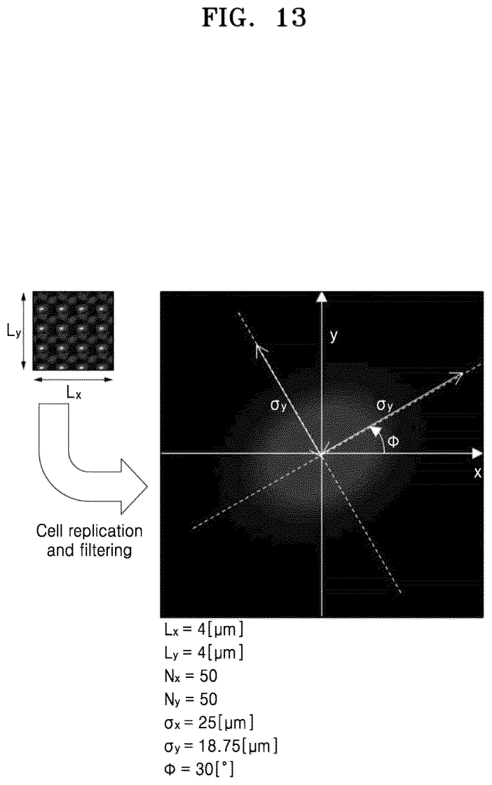

FIGS. 13 to 15 are diagrams illustrating other effects according to Embodiment 1.

FIG. 13 is a diagram illustrating a Gaussian filter used for comparison between the comparative example and Embodiment 1. Referring to FIG. 13, in the Gaussian filter, a near-field having a width of Lx=Ly=4 μm is replicated 50 times in the x and y directions, and a Gaussian function with a standard deviation of 125 μm and 93.75 μm in the x and y directions is rotated 30° from the x-axis to the y-axis.

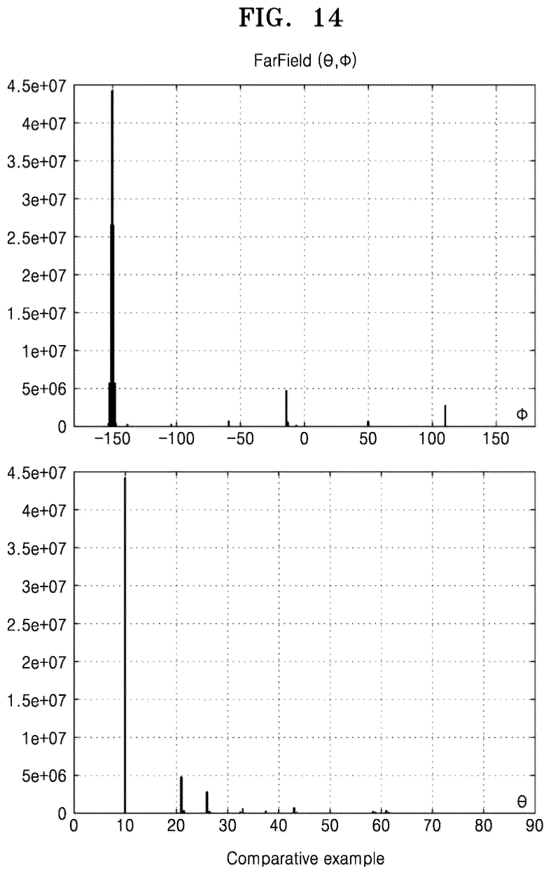

FIG. 14 is a diagram illustrating results of the far-field calculation in the comparative example when the Gaussian filter illustrated in FIG. 13 is applied. Referring to FIG. 14, in the comparative example using the Gaussian filter, noise caused by the discontinuity of the filter function appears.

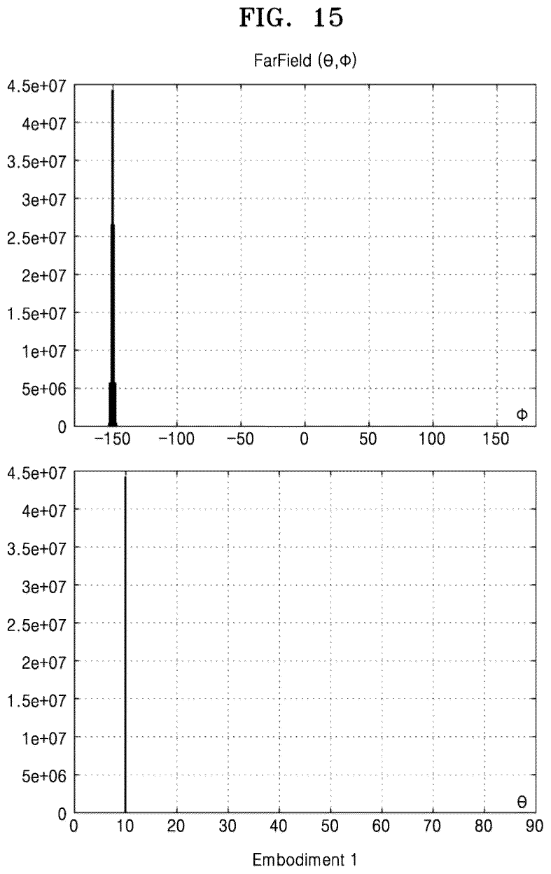

FIG. 15 is a diagram illustrating results of the far-field calculation in Embodiment 1 when the Gaussian filter illustrated in FIG. 13 is applied. Referring to FIG. 15, in Embodiment 1, such noise as in the comparative example does not appear. In this way, by executing Equation (1-3) using the analytic Fourier transform instead of Equation (17) using the double loop, the noise in the far-field calculation results may be suppressed.

In the variation of Embodiment 1, the computer 12 may determine the far-field using the far-field calculation method according to Embodiment 1 when a certain condition is satisfied, and may determine the far-field using the far-field calculation method according to the comparative example when the certain condition is not satisfied. The certain condition may be preset by a user. The certain condition may be, for example, that the number of a plurality of cells is greater than a certain number. By this variation of the embodiment, both the calculation speed and the calculation accuracy of the far-field may be ensured, because the far-field may be determined using the high-speed calculation method of the far-field according to Embodiment 1 only when the calculation requires a long time, for example.

In another variation of Embodiment 1, the far-field calculation instruction may include a user interface that allows the user to select whether to determine the far-field using the far-field calculation method of Embodiment 1 or the far-field calculation method of the comparative example. Specifically, when this far-field calculation instruction is executed, the computer 12 may display on the display 14 a “high-speed far-field calculation button” for selecting the calculation method of Embodiment 1, a “normal far-field calculation button” for selecting the calculation method of the comparative example, and a “run button” for instructing the far-field calculation. When the “run button” is selected after the “high-speed far-field calculation button” is selected by a user, the computer 12 may determine the far-field by using the far-field calculation method of Embodiment 1. When the “run button” is clicked after the “normal far-field calculation button” is clicked by the user, the computer 12 may determine the far-field by using the far-field calculation method of the comparative example. According to this variation of Embodiment 1, the user may select either Embodiment 1 or the comparative example as needed.

### Embodiment 2

In Embodiment 2, the computer 12 may determine a cell replication factor for each of a plurality of cells by using numerical Fourier transform of the filter function, stored in an array, including the elliptic filter or the Gaussian filter, and an interpolation function. Also by means of Embodiment 2, high-speed calculation of far-fields may be realized. Below, explanations of parts common to Embodiment 1 may be omitted.

When the filter function is a function that does not have an analytic Fourier transform, a discrete Fourier transform as shown below is obtained in advance and stored in memory as two-dimensional array data, and instead of the equation directly implemented by the analytic Fourier transform, this two-dimensional array is accessed to obtain the F˜(Kx, Ky) as needed.

$$\tilde{F} ( {K}_{x} [ m ] , {K}_{y} [ n ] ) = {\sum }_{\cdot } {\sum }_{\cdot } F ( x [ I ] , y [ J ] exp [ - i ( {K}_{x} [ m ] x [ I ] + {K}_{y} [ n ] y [ J ] ) ] \qquad ( 2 - 1 )$$

In Equation (2-1), I and J of x[I] and y[J] are integers denoting element indices when the filter function is represented as two-dimensional array data. Additionally, m and n in Kx[m] and Ky[n] are integers denoting element indices of the two-dimensional array data that stores the results of the discrete Fourier transform. Because the two-dimensional array data corresponding to F˜(Kx[m], Ky[n]) has the value F˜ only at the points Kx[m] and Ky[n] corresponding to the integers m and n, values at points between them are obtained by using interpolation such as linear interpolation or spline interpolation.

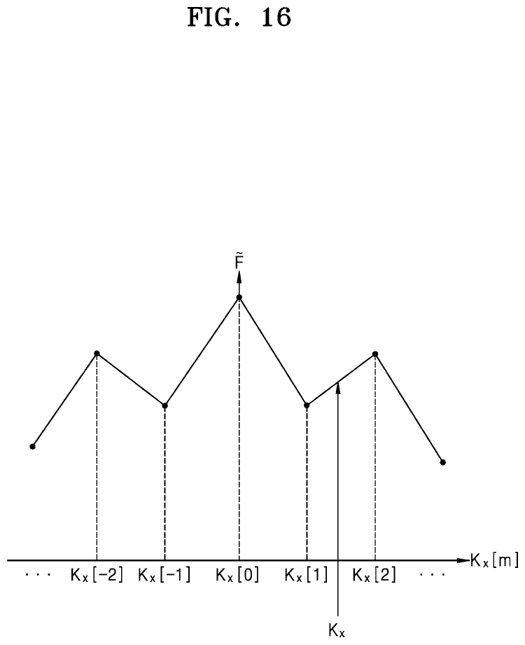

FIG. 16 is a diagram for explaining the interpolation method.

For ease of understanding, explanation may be given by using a one-dimensional diagram with reference to FIG. 16. For example, when trying to obtain the value F˜corresponding to a point Kx between Kx[1] and Ky[2] by the linear interpolation, a value may be obtained as in the following Equation (2-2).

$$\tilde{F} ( {K}_{x} ) = ( 1 - α ) \tilde{F} ( {K}_{x} [ 1 ] ) + α \tilde{F} ( {K}_{x} [ 2 ] ) \qquad ( 2 - 2 )$$

$$α = \frac{{K}_{x} - {K}_{x} [ 1 ]}{{K}_{x} [ 2 ] - {K}_{x} [ 1 ]}$$

Also, in Embodiment 2, the computer 12 may determine the far-field using the far-field calculation method according to Embodiment 2 when a certain condition is satisfied, and may determine the far-field using the far-field calculation method according to the comparative example when the certain condition is not satisfied. Additionally, in Embodiment 2, the far-field calculation instruction may include a user interface that allows the user to select whether to determine the far-field using the far-field calculation method of Embodiment 2 or the far-field calculation method of the comparative example.

### Embodiment 3

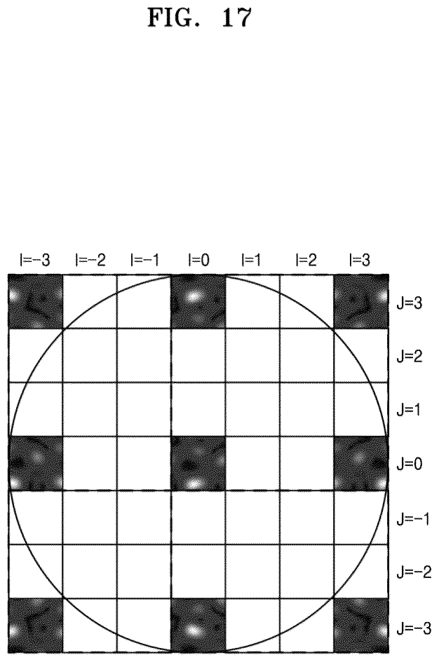

FIG. 17 is a diagram illustrating an example in which near-fields contributing to the far-field calculation do not have perfect periodicity.

Referring to FIG. 17, several near-field array data are given at positions separated from each other, and near-fields in regions between the positions may be expressed by interpolation between the given near-field arrays, and Equation (10) may be modified and represented as follows.

$${F}_{near} ( {x}_{i} , {y}_{j} ) = - {H}_{y} ( {x}_{i} , {y}_{j} ) cos θ cos ϕ + {H}_{x} ( {x}_{i} , {y}_{j} ) cos θ sin ϕ \qquad ( 3 - 1 )$$

$$Θ = {kx}_{i} sin θ cos ϕ + {ky}_{j} sin θsin ϕ + kz cos θ \qquad ( 3 - 2 )$$

By substituting Equation (3-1), (3-2), (11) into Equation (10), Equation (10) can be rewritten as follows.

$${N}_{θ} ( θ , ϕ ) = {\sum }_{i} {\sum }_{j} {F}_{near} ( {x}_{i} , {y}_{j} ) {e}^{- i θ} - Δ {x}_{i} Δ {y}_{j} {\sum }_{I} {\sum }_{J} F ( {x}_{i} + {IL}_{x} , {y}_{j} + {JL}_{y} ) {e}^{- {iK}_{x} {IL}_{x}} {e}^{- {iK}_{y} {JL}_{y}} \qquad ( 3 ‐ 3 )$$

Here, the region where 0≤I≤3 and 0≤J≤3 is defined as Region 1, the region where −3≤I<0 and 0≤J≤3 is defined as Region 2, the region where −3≤I<0 and −3≤J<0 is defined as Region 3, and the region where 0≤I≤3 and −3≤J<0 is defined as Region 4.

A near-field F1(xi, yj) of Region 1, when near-fields at a lower-left corner, a lower-right corner, an upper-left corner, and an upper-right corner given to this region are defined as F₀₀¹, F₀₁¹, F₁₀¹, and F₁₁¹, respectively, may be expressed as follows by interpolation of these fields.

$${F}^{1} = ( 1 - s ) ( 1 - t ) {F}_{00}^{1} + ( 1 - s ) t {F}_{01}^{1} + s ( 1 - t ) {F}_{10}^{1} + {stF}_{11}^{1} \qquad ( 3 ‐ 4 )$$

The parameters s and t may be expressed, for example, by cell numbers Is and Js in the lower left of a region focused on, by Wx and Wy, and by the width of one cycle of the near field, Lx and Ly.

$$s = \frac{{L}_{x}}{{W}_{x}} ( I - {I}_{s} ) , t = \frac{{L}_{y}}{{W}_{y}} ( J - {J}_{s} ) \qquad ( 3 ‐ 5 )$$

When interpolation coefficients of Equation (3-4) are defined as c₀₀¹=(1−s)(1−t), c₀₁¹=(1−s)t, c₁₀¹=s(1−t), c₁₁¹=st, Equation (3-4) may be expressed using a summation symbol as follows.

$${F}^{1} = {c}_{00}^{1} {F}_{00}^{1} + {c}_{01}^{1} {F}_{01}^{1} + {c}_{10}^{1} {F}_{10}^{1} + {c}_{11}^{1} {F}_{11}^{1} = {\sum }_{k = 0}^{1} {\sum }_{l = 0}^{1} {c}_{kl}^{1} {F}_{kl}^{1} \qquad ( 3 ‐ 6 )$$

By using Equation (3-6), Equation (3-3), when Region 1 is focused on, may be expressed as follows.

$${N}_{θ}^{1} ( θ , ϕ ) = {\sum }_{i} {\sum }_{j} {\sum }_{k = 0}^{1} {\sum }_{l = 0}^{1} {c}_{k l}^{1} {F}_{k l}^{1} ( {x}_{i} , {y}_{j} ) {e}^{- i Θ} Δ {x}_{i} Δ {y}_{j} {\sum }_{I = 0}^{3} {\sum }_{J = 0}^{3} F ( {x}_{i} + {IL}_{x} , {y}_{j} + {JL}_{y} ) {e}^{- {iK}_{x} {IL}_{x}} {e}^{- {iK}_{y} {JL}_{y}} \qquad ( 3 ‐ 7 )$$

Coefficients and superscripts of functions in this equation represent region numbers. Here, although, for simplicity, a region where 0≤I≤3 and 0≤J≤3 is defined as Region 1, when further generalizing this definition and defining a region where Iₛ^{m}≤I≤Iₑ^{m} and Jₛ^{m}≤J≤J_{c}^{m} as Region m, Equation (3-6), when Region m is focused on, may be expressed as follows.

$${N}_{θ}^{m} ( θ , ϕ ) = {\sum }_{i} {\sum }_{j} {\sum }_{k = 0}^{1} {\sum }_{l = 0}^{1} {c}_{kl}^{m} {F}_{kl}^{m} ( {x}_{i} , {y}_{j} ) {e}^{- i Θ} Δ {x}_{i} Δ {y}_{j} {\sum }_{I = {I}_{s}^{m}}^{{I}_{e}^{m}} {\sum }_{J = {J}_{s}^{m}}^{{I}_{e}^{m}} F ( {x}_{i} + {IL}_{x} , {y}_{j} + {JL}_{y} ) {e}^{- {iK}_{x} {IL}_{x}} {e}^{- {iK}_{y} {JL}_{y}} = {\sum }_{i} {\sum }_{j} {\sum }_{k = 0}^{1} {\sum }_{l = 0}^{1} {F}_{kl}^{m} ( {x}_{i} , {y}_{j} ) {e}^{- i Θ} Δ {x}_{i} Δ {y}_{j} {\sum }_{I = {I}_{s}^{m}}^{{I}_{e}^{m}} {\sum }_{J = {J}_{s}^{m}}^{{I}_{e}^{m}} {c}_{kl}^{m} F ( {x}_{i} + {IL}_{x} , {y}_{j} + {JL}_{y} ) {e}^{- {iK}_{x} {IL}_{x}} {e}^{- {iK}_{y} {JL}_{y}} = {\sum }_{i} {\sum }_{j} {\sum }_{k = 0}^{1} {\sum }_{l = 0}^{1} {F}_{kl}^{m} ( {x}_{i} , {y}_{j} ) {e}^{- i Θ} Δ {x}_{i} Δ {y}_{j} {F}_{kl , CellCopy}^{m} \qquad ( 3 ‐ 8 )$$

$${F}_{kl , CellCopy}^{m} = {\sum }_{I = {I}_{s}^{m}}^{{I}_{e}^{m}} {\sum }_{J = {J}_{s}^{m}}^{{I}_{e}^{m}} {c}_{k l}^{m} F ( {x}_{i} + {IL}_{x} , {y}_{j} + {JL}_{y} ) {e}^{- i {K}_{x} {IL}_{x}} {e}^{- i {K}_{y} {JL}_{y}} \qquad ( 3 ‐ 9 )$$

Additionally, by determining and adding Equation (3-7) for each region, Nθ(θ, Φ) for an entire region may be obtained, and the same equation transformation may also be applied to NΦ(θ, Φ), Lθ(θ, Φ), and LΦ(θ, Φ), and by assigning a function name on the left side to a subscript such that Fₖₗ^{m} may be distinguished, expressions may be written as Equations (3-10) to (3-13) below. For the cell replication factor, Gₖₗ^{m}(x, y)=cₖₗ^{m}F(x, y) is defined as a new filter function in Equation (3-9). This “Gum” is an interpolation coefficient. When the Fourier transform is set as G˜ₖₗ^{m}(Kₓ, K_{y}), an expression such as Equation (3-14) may be represented. By performing the equation transformation, the equation may be transformed into Equation (3-15), and high-speed calculation becomes possible.

$${N}_{θ} ( θ , ϕ ) = {\sum }_{m} {\sum }_{i} {\sum }_{j} {\sum }_{k = 0}^{1} {\sum }_{l = 0}^{1} {F}_{k l , {N}_{θ}}^{m} ( {x}_{i} , {y}_{j} ) {e}^{- i Θ} Δ {x}_{i} Δ {y}_{j} {F}_{kl , CellCopy}^{m} \qquad ( 3 ‐ 10 )$$

$${N}_{ϕ} ( θ , ϕ ) = {\sum }_{m} {\sum }_{i} {\sum }_{j} {\sum }_{k = 0}^{1} {\sum }_{l = 0}^{1} {F}_{kl , {N}_{ϕ}}^{m} ( {x}_{i} , {y}_{j} ) {e}^{- i Θ} Δ {x}_{i} Δ {y}_{j} {F}_{kl , CellCopy}^{m} \qquad ( 3 ‐ 11 )$$

$${L}_{θ} ( θ , ϕ ) = {\sum }_{m} {\sum }_{i} {\sum }_{j} {\sum }_{k = 0}^{1} {\sum }_{l = 0}^{1} {F}_{kl , {L}_{θ}}^{m} ( {x}_{i} , {y}_{j} ) {e}^{- i Θ} Δ {x}_{i} Δ {y}_{j} {F}_{kl , CellCopy}^{m} \qquad ( 3 ‐ 12 )$$

$${L}_{ϕ} ( θ , ϕ ) = {\sum }_{m} {\sum }_{i} {\sum }_{j} {\sum }_{k = 0}^{1} {\sum }_{l = 0}^{1} {F}_{kl , {L}_{ϕ}}^{m} ( {x}_{i} , {y}_{j} ) {e}^{- i Θ} Δ {x}_{i} Δ {y}_{j} {F}_{kl , CellCopy}^{m} \qquad ( 3 ‐ 13 )$$

$${F}_{kl , CellCopy}^{m} = \{ \begin{matrix}{\sum }_{I = {I}_{s}^{m}}^{{I}_{e}^{m}} {\sum }_{J = {J}_{s}^{m}}^{{I}_{e}^{m}} {G}_{kl}^{m} ( {x}_{i} + {IL}_{x} , {y}_{j} + {JL}_{y} ) {e}^{- {iK}_{x} {IL}_{x}} {e}^{- {iK}_{y} {JL}_{y}} & ( 3 ‐ 14 ) \\ \frac{{\overline{G}}_{kl}^{m} ( {K}_{x} , {K}_{y} )}{{L}_{x} {L}_{y}} {e}^{+ i ( {K}_{x} {x}_{i} + {K}_{y} {y}_{j} )} ( cell width << filter width ) & ( 3 ‐ 15 )\end{matrix}$$

A specific calculation flow may proceed as follows. First, a near-field electromagnetic-field on a top surface of a target structure may be determined using the FDTD method or the RCWA method. By substituting the near-field electromagnetic-field into Equations (3-10) to (3-13), Nθ(θ, Φ), NΦ(θ, Φ), Lθ(θ, Φ), and LΦ(θ, Φ) may be determined. A high-speed method of Equation (3-15) may be used instead of a normal method of Equation (3-14). Because the Fourier transform G˜ₖₗ^{m}(Kₓ, K_{y}) of Equation (3-15) is multiplied by an interpolation coefficient and is generally difficult to obtain analytically, a function may be prepared in advance to store a result of numerically Fourier-transforming a discretized Gₖₗ^{m}(x, y) in a memory and to return a value corresponding to specified arguments Kx and Ky from the memory together with interpolation, and by using this function, the Fourier transform G˜ₖₗ^{m}(Kx, Ky) may be obtained. Here, by substituting Nθ(θ, Φ), NΦ(θ, Φ), Lθ(θ, Φ), and LΦ(θ, Φ) obtained by the high speed method into Equation (4), the far-field in the direction represented by (θ, Φ) may be determined. By repeatedly performing this calculation for all (θ, Φ) directions, the far-field distribution may be obtained.

In this embodiment, the region is divided into four, but the number of region divisions is not limited to four from the generalized Equations (3-9) to (3-12). Compared with the equation in Embodiment 1, loops for a region number m and for interpolation coefficients are added, and the number of region divisions may be 2×2=4 or 3×3=9. The loop for linear interpolation is fixed to four values of kl=00, 01, 10, and 11.

By determining the cell replication factor by using Fourier transform in this manner, it was confirmed that the calculation time that required several days was reduced to several seconds or minutes, and that the calculation speed after the reduction increased by up to four times the maximum number of region divisions, which may be regarded as sufficiently high-speed compared to the conventional method.

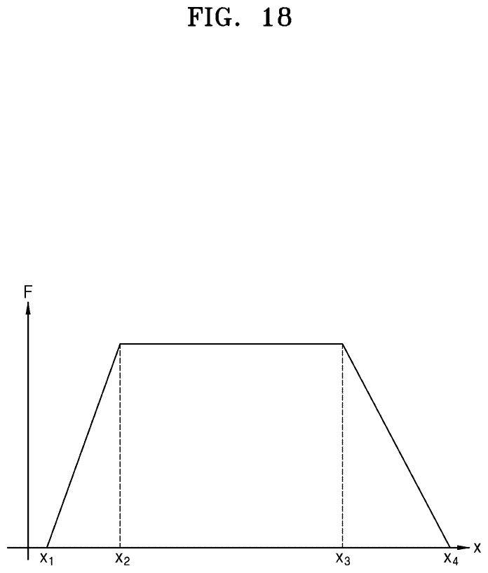

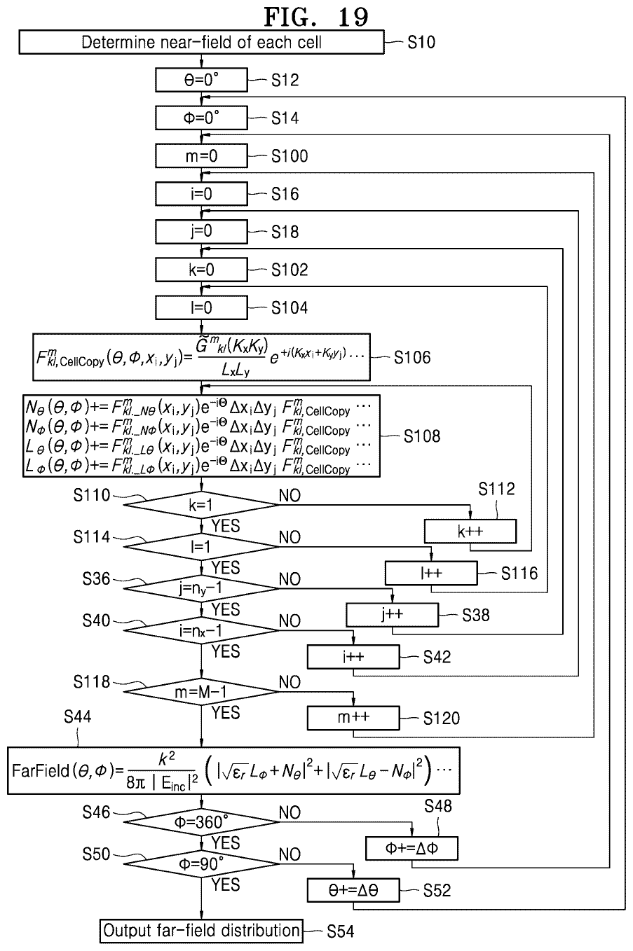

FIG. 19 is a flowchart illustrating a far-field calculation process when the far-field calculation instruction for Embodiment 3 is executed by the computer 12. Hereinafter, identical reference symbols are given for the same operations as the above-described flowchart, and descriptions thereof are omitted.

Referring to FIG. 19, the computer 12 may set the initial values of θ, Φ, m, i, j, k, and 1 to 0 (operations S12, S14, S100, S16, S18, S102, and S104). Next, the computer 12 may determine the cell replication factor using Equation (3-15) (operation S106).

The computer 12 may determine the second factor of Nθ, NΦ, Lθ, and LΦ by using the cell replication factor when determining the cell replication factor (operation S108). When the second factor is determined, the computer 12 may determine whether k is equal to 1 (operation S110), and if not (“NO” of operation S110), increments k (operation S112) and may return to operation S108. If k is equal to 1 (“YES” in operation S110), the computer 12 may determine whether 1 is equal to 1 (operation S114), and if not (“NO” in operation S114), may increment 1 (operation S116) and may return to operation S104.

Also, if nx−1 is equal to I (“YES” in operation S40), the computer 12 may determine whether m is equal to M−1 (operation S118), and if not (“NO” in operation S118), may increment m (operation S120) and may return to operation S14. If m is equal to M−1 (“YES” in operation S118), the computer 12 may determine the far-field using Equation (4) (operation S44).

In this way, in Embodiment 3, the computer 12 may determine the cell replication factor necessary for determining the far-field for each of a plurality of cells by using the interpolation coefficient “Gₖₗ^{m}” multiplied by a filter function including the elliptic filter, the Gaussian filter, or the like. Additionally, the computer 12 may, for some cells, determine the far-field of the target structure by using the near-fields of those cells and the cell replication factors of those cells. Furthermore, in a cell located in an area between some cells, the computer 12 may determine the far-field of the target structure by using the near-fields of the some cells and the cell replication factors of those cell, which is determined by linear or higher-order approximation from the factors of those cells. In addition, in Embodiment 3, in a cell located in an area between some cells, a cell replication factor may be used, which is determined by linear or higher-order approximation from the factors of some cells. Because of this, it becomes possible to determine the far-field of a target structure at higher speed.

As a variation of Embodiment 3, a case may be considered in which the given near-field arrays have symmetry with respect to translation or inversion as a whole. In this case, near-fields corresponding to the remaining regions (for example, the second to fourth quadrants in FIG. 17) may be generated from near-fields in a partial region (for example, the first quadrant in FIG. 17), and by using these near-fields as the entire near-field, the high-speed calculation method described above may be applied.

In addition, when it is possible to determine a desired far-field by assigning a weight corresponding to a range in which light is reflected or transmitted to the given near-field array, the filter function in Equation (3-9) may be regarded as constant at 1 by assigning the weight corresponding to the filter function to the near-field array. Therefore, the following expression may be derived.

$${F}_{kl , CellCopy}^{m} = {\sum }_{I = {I}_{s}^{m}}^{{I}_{e}^{m}} {\sum }_{J = {J}_{s}^{m}}^{{I}_{e}^{m}} {c}_{kl}^{m} {e}^{- {iK}_{x} {IL}_{x}} {e}^{- {iK}_{y} {JL}_{y}} \qquad ( 3 ‐ 16 )$$

However, because cₖₗ^{m} is a linear function of I and J, the result may be obtained without performing numerical calculation by finding a sum of a sequence having the form shown below with a and b as constants.

$${S}_{x} = a {\sum }_{I = {I}_{s}^{m}}^{{I}_{e}^{m}} I {e}^{- i {K}_{x} {IL}_{x}} \qquad ( 3 ‐ 17 )$$

$${S}_{y} = b {\sum }_{J = {J}_{s}^{m}}^{{I}_{e}^{m}} {Je}^{- i {K}_{y} {JL}_{y}} \qquad ( 3 ‐ 18 )$$

In fact, a sum of a geometric sequence with multiplied term numbers, such as Equations (3-17) and (3-18), may be determined as follows.

$$S = a {\sum }_{i = {i}_{s}}^{{i}_{e}} i {r}^{i} = a {r}^{{i}_{s}} ( {i}_{s} \frac{1 - {r}^{n}}{1 - r} - \frac{{nr}^{n}}{1 - r} + \frac{r}{1 - r} \frac{1 - {r}^{n}}{1 - r} ) \qquad ( 3 ‐ 19 )$$

Wherein n is the number of terms in the sequence and n=iₑ−iₛ₊₁. The case of r=1 is omitted here because it is simply a sum of an arithmetic sequence. In this Equation (3-18), if r=e^{-iKx ILx}, iₛ=Iₛ^{m}, ie=Iₑ^{m}, and in Equation (3-17), if r=e^{-iKyJLy}, iₛ=Jₛ^{m}, iₑ=Jₑ^{m}, Equation (3-19) may be determined. In addition, when it is possible to determine a desired far-field by assigning a weight corresponding to a range in which light is reflected or transmitted to the given near-field array, that is, when the weight corresponding to the filter function is assigned to the term of the near-field array such that the filter function in Equation (3-9) may be regarded as constant at 1, high-speed far-field calculation may be realized by applying Equation (5-1) instead of Equations (3-14) and (3-15) to the cell replication factors in Equations (3-10) to (3-13). Because this Equation is not an approximate equation, it may be determined exactly for the entire given near-field array.

In this way, in the variation of Embodiment 3, the plurality of cells included in the target structure may be divided into a first cell group and a second cell group having symmetry or anti-symmetry with respect to translation or inversion of the first cell group. In this case, the computer 12 may determine the near-field of each of a plurality of cells included in the first cell group using the electromagnetic-field analysis method. The computer 12 may determine the far-field using the near-field and the cell replication factor of each cell in the plurality of cells included in the first cell group. The computer 12, for a plurality of cells included in the second cell group, may determine the far-field of the target structure by using the near-fields of the cells, among the plurality of cells included in the first cell group having symmetry or anti-symmetry, respectively corresponding to the plurality of cells included in the second cell group, and by using the cell replication factors of the plurality of cells included in the second cell group. The point that the computer 12 determines the cell replication factor necessary for determining the far-field for each of the plurality of cells using the filter function including the elliptic filter or the Gaussian filter is identical with the comparative example.

In this way, in the variation of Embodiment 3, for the plurality of cells included in the second cell group, the near-field of the target structure may be determined by using the cell replication factor of the corresponding cell of the first cell group having symmetry or anti-symmetry and the cell replication factors of the plurality of cells included in the second cell group. As a result, the far-field of the target structure may be determined at high speed.

Also in Embodiment 3, the computer 12 may determine the far-field by using the far-field calculation method according to Embodiment 3 when a certain condition is satisfied, and may determine the far-field by using the far-field calculation method according to the comparative example when the certain condition is not satisfied. Also in Embodiment 3, the far-field calculation instruction may provide a user interface that allows the user to select whether to determine the far-field by using the far-field calculation method of Embodiment 3 or the far-field calculation method of the comparative example.

### Embodiment 4

In Embodiment 4, the computer 12 may determine the cell replication factor for each of the plurality of cells using analytical calculation of a weighted geometric series. An operation, in which the computer 12 may determine the near-field of each of the plurality of cells included in the target structure by using the electromagnetic-field analysis method, and an operation in which the computer 12 may determine the far-field of the target structure by using the near-field of each of the plurality of cells and the cell replication factor, are identical to those of the comparative example described above. Also by means of this variation, it becomes possible to determine the far-field of a target structure at higher speed.

FIG. 18 is a diagram illustrating an example of a one-dimensional filter function. For ease of understanding, a one-dimensional filter function is described by way of example.

Referring to FIG. 18, in the region of x2≤x<x3, a cell replication factor may be determined by using a sum of a geometric series of Equation (1-7), and in the regions of x1≤x<x2 and x3≤x<x4, it may be determined by using a sum of the weighted geometric series of Equation (3-19). Even though this filter is two-dimensional, the filter function may be separated into x and y directions and the same calculation may be applied to each direction.

Also in Embodiment 4, the computer 12 may determine the far-field using the far-field calculation method according to Embodiment 4 when a certain condition is satisfied, and may determine the far-field using the far-field calculation method according to the comparative example when the certain condition is not satisfied. Also in Embodiment 4, the far-field calculation instruction may provide a user interface that allows the user to select whether to determine the far-field using the far-field calculation method of Embodiment 4 or the far-field calculation method of the comparative example.

### Embodiment 5

FIG. 20 is a diagram illustrating an example in which some cells include defects.

Referring to FIG. 20, as the near-field Fₙₑₐᵣ in a normal cell, in the case where an abnormal near-field F_{defect} exists in the (I_{defect}, J_{defect})th cell among these arrays, Equations (1-7), (3-1), and (3-2) in Embodiment 2 can be rewritten in a modified form as follows.

$$N ( θ , ϕ ) = {\sum }_{i} {\sum }_{j} {F}_{near} [ i , j ] {e}^{- i Θ} Δ {x}_{i} Δ {y}_{i} {\sum }_{I \neq {I}_{defect}} {\sum }_{J \neq {J}_{defect}} {F}_{filter} ( {x}_{i} + {IL}_{x} , y + {JL}_{y} ) {e}^{- i {K}_{x} {IL}_{x}} {e}^{- i {K}_{y} {JL}_{y}} + {\sum }_{i} {\sum }_{j} {F}_{defect} [ i , j ] {e}^{- i Θ} Δ {x}_{i} Δ {y}_{j} {F}_{filter} ( {x}_{i} + {I}_{defect} {L}_{x} , y + {J}_{defec𝔱} {L}_{y} ) {e}^{- {iK}_{x} {I}_{defect} {L}_{x}} {e}^{- {iK}_{y} {J}_{defect} {L}_{y}} \qquad ( 5 ‐ 1 )$$

When a term that is added and subtracted to compensate for a portion excluded from the first term on the right-hand side is newly added to the right-hand side, it may be expressed as follows.

$$N ( θ , ϕ ) = {\sum }_{i} {\sum }_{j} {F}_{near} [ i , j ] {e}^{- i Θ} Δ {x}_{i} Δ {y}_{j} {\sum }_{I \neq {I}_{defect}} {\sum }_{J \neq {J}_{defect}} {F}_{filter} ( {x}_{i} + {IL}_{x} , y + {JL}_{y} ) {e}^{- i {K}_{x} {IL}_{x}} {e}^{- i {K}_{y} {IL}_{y}} + {\sum }_{i} {\sum }_{j} {F}_{defect} [ i , j ] {e}^{- i Θ} {Δx}_{i} {Δy}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} - {\sum }_{i} {\sum }_{j} {F}_{near} [ i , j ] {e}^{- i Θ} Δ {x}_{i} Δ {y}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} - {\sum }_{i} {\sum }_{j} {F}_{near} [ i , j ] {e}^{- i Θ} Δ {x}_{i} Δ {y}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} \qquad ( 5 ‐ 2 )$$

The sum of the first and third terms on the right-hand side may correspond to a completely periodic near-field in a case where no defect is present.

$$N ( θ , ϕ ) = {\sum }_{i} {\sum }_{j} {F}_{near} [ i , j ] {e}^{- i Θ} Δ {x}_{i} Δ {y}_{j} {\sum }_{I} {\sum }_{J} {F}_{filter} ( {x}_{i} + {IL}_{x} , y + {JL}_{y} ) {e}^{- i {K}_{x} {IL}_{x}} {e}^{- i {K}_{y} {IL}_{y}} + {\sum }_{i} {\sum }_{j} {F}_{defect} [ i , j ] {e}^{- i Θ} Δ {x}_{i} Δ {y}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} - {\sum }_{i} {\sum }_{j} {F}_{near} [ i , j ] {e}^{- i Θ} Δ {x}_{i} Δ {y}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} \qquad ( 5 ‐ 3 )$$

By rearranging the remaining terms, Equation (5-1) in a case where the defect is included may be separated as follows into a term corresponding to the completely periodic case without defects and a term related to an effect caused by the defect.

$$N ( θ , ϕ ) = {\sum }_{i} {\sum }_{j} {F}_{near} [ i , j ] {e}^{- i Θ} Δ {x}_{i} Δ {y}_{j} {F}_{CellCopy} + {\sum }_{i} {\sum }_{j} {F}_{defect} [ i , j ] - {F}_{near} [ i , j ] {e}^{- i Θ} Δ {x}_{i} Δ {y}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} \qquad ( 5 ‐ 4 )$$

The first term of Equation (5-4) is a form to which the high-speed calculation method may be applied. Although a case with one defect is described here as an example, even if two or more defects are present, only terms of the form of the second term increase, and therefore Equation (5-4) may be expanded as follows by defining the number of defective cells as N_defect.

$$N ( θ , ϕ ) = {\sum }_{i} {\sum }_{j} {F}_{near} [ i , j ] {e}^{- i Θ} Δ {x}_{i} Δ {y}_{j} {F}_{CellCopy} + {\sum }_{defect = 1}^{{N}_{defect}} {\sum }_{i} {\sum }_{j} {F}_{defect} [ i , j ] {e}^{- i Θ} Δ {x}_{i} {Δy}_{j} {F}_{filter} ( {x}_{i} + {I}_{defect} {L}_{x} , y + {J}_{defect} {L}_{y} ) {e}^{- {iK}_{x} {I}_{defect} {L}_{x}} {e}^{- {iK}_{y} {J}_{defect} {L}_{y}} \qquad ( 5 ‐ 5 )$$

NΦ(θ, Φ), Lθ(θ, Φ), and LΦ(θ, Φ) may also be obtained in the same way.

Accordingly, near electromagnetic fields in a case without defects and near-fields at defect positions on the top surface of a target structure obtained by FDTD or RCWA may be obtained, and these near electromagnetic fields may be substituted into Equation (5-5) to obtain Nθ(θ, Φ), NΦ(θ, Φ), Lθ(θ, Φ), and LΦ(θ, Φ). Instead of the equation corresponding to the normal method Equation (17) in Embodiment 1, the high-speed method Equation (1-1) may be applied. Here, by substituting Nθ(θ, Φ), NΦ(θ, Φ), Lθ(θ, Φ), and LΦ(θ, Φ) obtained at high speed into Equation (4), the far-field in the direction of (θ, Φ) may be obtained. This calculation is repeated for all (θ, Φ) directions for which the far-field distribution is to be obtained. Compared with the equation in Embodiment 1, a loop for the defect is added, and as described in the effects of the disclosure below, by determining the cell replication factor for the completely periodic part by Fourier transform, the calculation that requires several days is reduced to several seconds or minutes, and therefore the calculation speed after the reduction may be increased by up to several times the number of loops of I and J and may be considered sufficiently high compared with the conventional method.

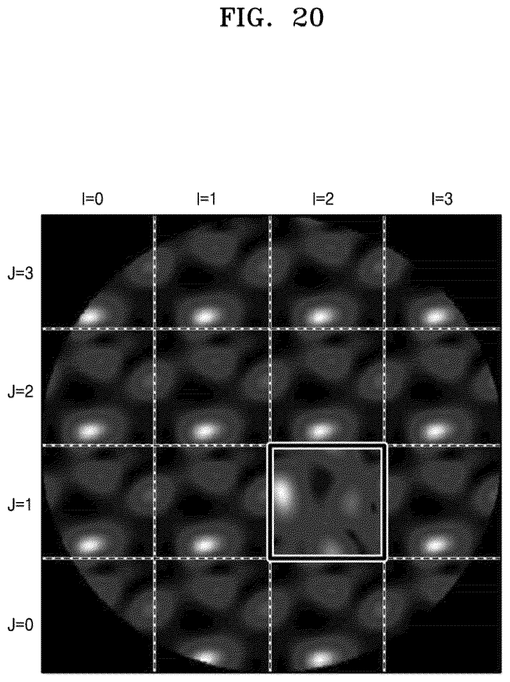

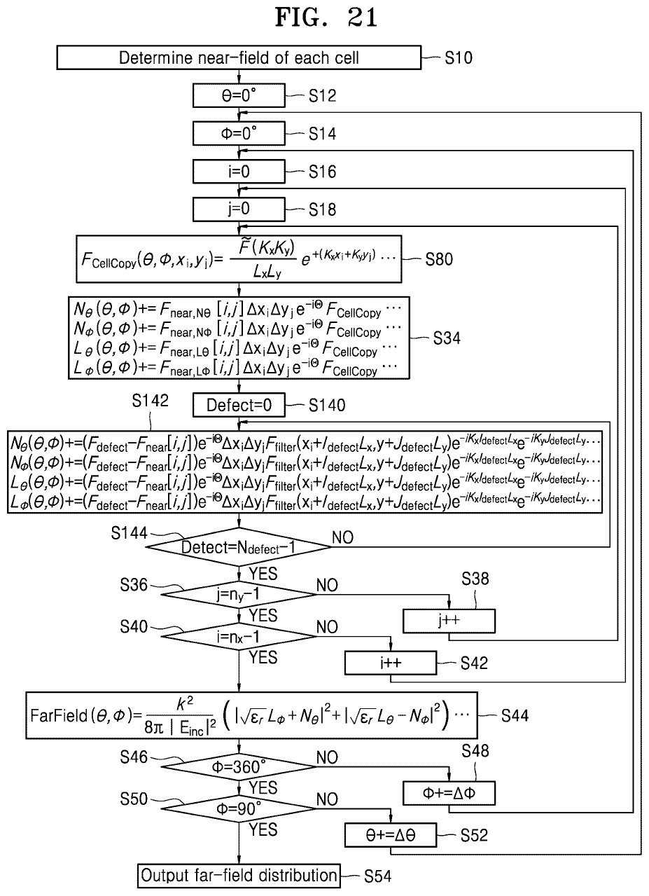

FIG. 21 is a flowchart illustrating the far-field calculation processing procedure when the far-field calculation instruction for Embodiment 5 is executed on the computer 12. Hereinafter, identical reference symbols are given for the same operations as the above-described flowchart, and descriptions thereof are omitted. Hereinafter, “defect” means the defective cell number.

Referring to FIG. 21, in Embodiment 5, the computer 12 may perform operation S80 instead of operations S20, S22, S24, S26, S28, S30, and S32 of FIG. 6 in the comparative example. That is, in Embodiment 5, the computer 12 may determine the cell replication factor for each of the plurality of cells by using the transform function that is the analytic Fourier transform of the filter function including the elliptic filter or the Gaussian filter.

After operation S80, the computer 12 may set defect=0, that is, the cell is regarded as having no defect (operation S140). The computer 12 may, after operation S140, determine Nθ(θ, Φ), NΦ(θ, Φ), Lθ(θ, Φ), and LΦ(θ, Φ) using Equation (5-5) (operation S142). After operation S142, the computer 12 may determine whether the defect is identical to N_{defect}−1 (operation S144). If the defect is not identical to N_{defect}−1 (“NO” in operation S144), the process returns to operation S142. If the defect is identical to N_{defect}−1 (“YES” in operation S144), the process may proceed to operation S36.

In this way, in Embodiment 5, when a defective cell is included among the plurality of cells, the computer 12 may determine, through the operation of determining the near-field, the near-field of each of the plurality of cells in a case where no defective cell is included, and the near-field of the defective cell. Furthermore, when determining the far-field, the computer 12 may determine the far-field in a case where a defective cell is included among the plurality of cells by adding an effect given to the far-field by the near-field of the defective cell, during a procedure of determining the far-field by using the near-field of each of the plurality of cells in a case where no defective cell is included. According to Embodiment 5, even when the defective cell is included among the plurality of cells, the far-field may be accurately and quickly determined.

Also, in a variation of Embodiment 5, the computer 12 may determine the far-field by applying the far-field calculation method according to Embodiment 5 when a certain condition is satisfied, and may determine the far-field by applying the far-field calculation method according to the comparative example when the certain condition is not satisfied. Also in a variation of Embodiment 5, the far-field calculation instruction may provide a user interface that allows the user to select whether to determine the far-field by using the far-field calculation method of Embodiment 5 or the far-field calculation method of the comparative example.

### Embodiment 6

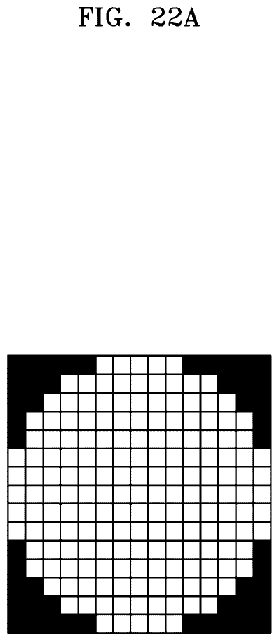

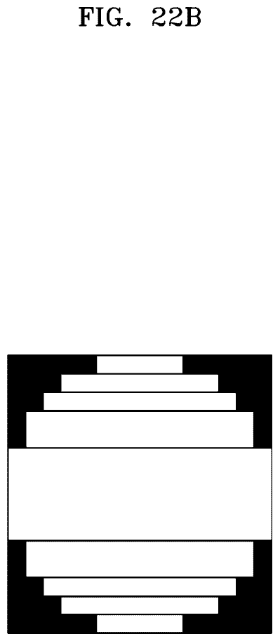

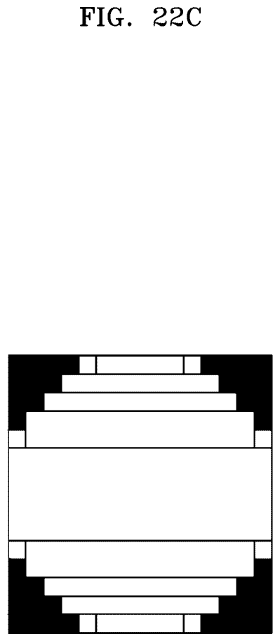

In Embodiment 6, a structure similar to that in FIG. 2 is periodically arranged, and a case may be considered, in which the far-field, formed by reflected light when light having circular diffusion as in FIG. 3 is incident, is determined at high speed by applying the exact solution of a geometric series. FIG. 22A is a diagram illustrating an example of a plurality of cells in which cells with a filter function of 1 are white cells and cells with a filter function of 0 are black cells.

FIG. 22B is a diagram illustrating rectangular areas extracted from FIG. 22A. When rectangular areas are extracted in this way, Equations (1-6) and (1-7) may be applied to nine merged rectangular areas. In addition, calculation may be omitted for a portion corresponding to the black cells because the value of the filter function is 0. The calculation time may be reduced because the calculation of the cell replication factor using Equations (1-6) and (1-7) is sufficiently faster than the calculation using the double loop.

FIG. 22C is a diagram illustrating a case in which the outer circumference of a circle has a value between 0 and 1. Even in such a case, for example, portions having a value of 1 are combined into a rectangular area and determined using Equations (1-6) and (1-7), calculation for portions having a value of 0 are omitted, and portions having a value between 0 and 1 are determined individually, thereby the calculation speed becomes sufficiently faster than the calculation using the original double loop. Furthermore, even when the filter function is divided into domains as in embodiments 2 and 3, has symmetry, or includes any defect, a method of extracting rectangular areas capable of having the exact solution of the geometric series applied thereto and applying the exact solution to the extracted areas may be applicable.

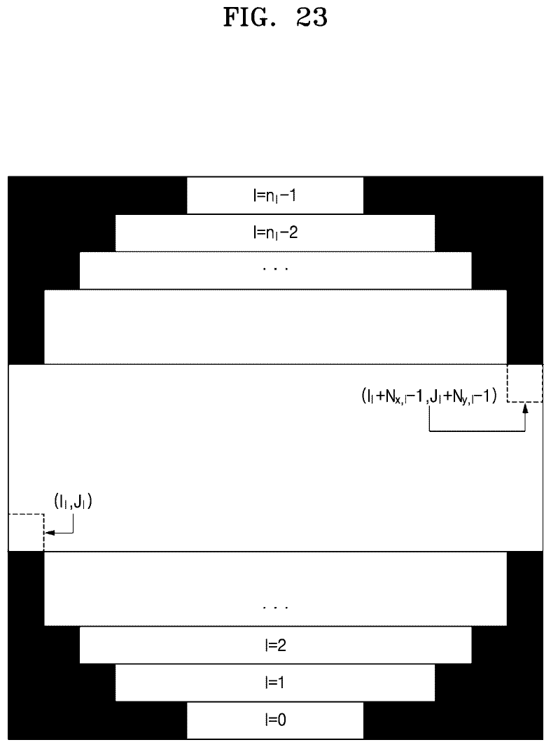

FIG. 23 is a diagram illustrating a specific method of the rectangular area extracted in FIG. 22C.

Referring to FIG. 23, l denotes an index of the extracted rectangular area, and nl denotes a total number of the rectangular areas. (Iₗ, Jₗ) denotes a cell index of the smaller side of region l, and Nx,l, and Ny,l denote a total number of cells in the x and y directions of region l.

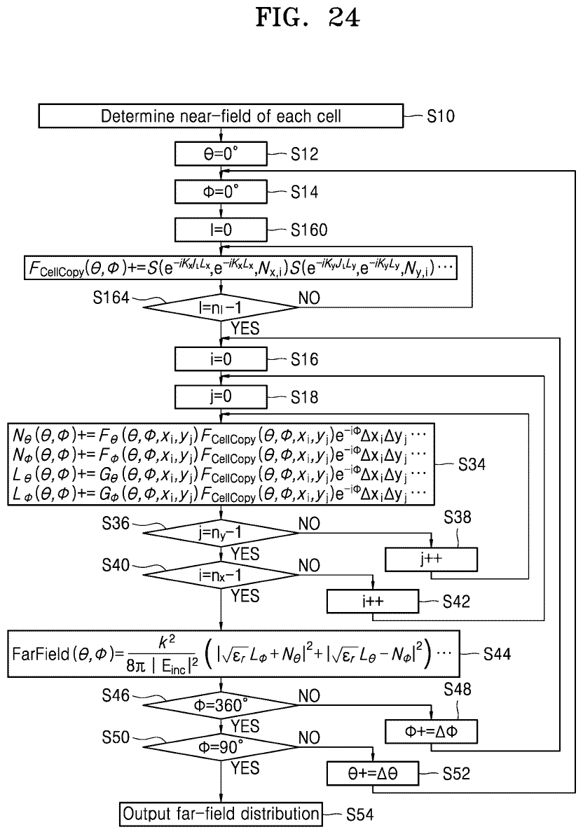

FIG. 24 is a flowchart illustrating the far-field calculation process when the far-field calculation instruction for Embodiment 6 is executed on the computer 12. Hereinafter, identical reference symbols are given for the same operations as the above-described flowchart, and descriptions thereof may be omitted.

Referring to FIG. 24, in Embodiment 6, the procedures of operations S20, S22, S24, S26, S28, S30, and S32 of FIG. 6 in the comparative example are omitted. However, operations S160, S162, and S164 are added between operations S14 and S16.

After operation S14, the computer 12 may determine the cell replication factor using the Equation (21′), which is a slightly modified version of Equation (1-6) (operation S162). Equation (21′) is an equation in which “e^{-iKx Il Lx}, e^{-iKx Jl Ly}” are substituted into the first term ‘a’ in Equation (1-7). After operation S162, the computer 12 may determine whether l is equal to nl−1 (operation S164). If l is not equal to nl−1, return to operation S162. If l is equal to nl−1, proceeding to operation S16 may be performed.

In this way, in Embodiment 6, the operation of determining the cell replication factor, when certain rectangular areas in which the value of the filter function is not 0 exist, may include an operation in which the computer 12 determines first and second factors by using the exact solution of the geometric series for each of the rectangular areas.

Also, in Embodiment 6, the computer 12 may extract a certain rectangular area while the value of the filter function is not 0. The computer 12 may determine the first and second factors by using the exact solution of the geometric series for each of the rectangular areas extracted by the computer 12. A user may directly specify a rectangular area where the value of the filter function is not 0. In this case, the computer 12 may determine the first and second factors by using the exact solution of the geometric series for each of the rectangular areas specified by the user.

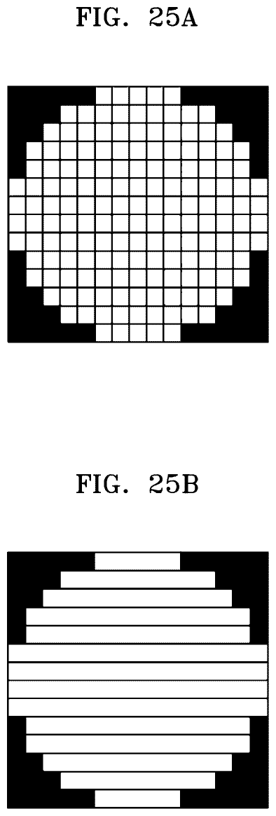

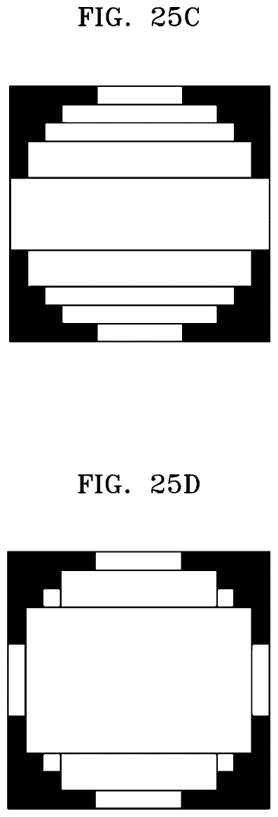

FIGS. 25A, 25B, 25C, and 25D are diagrams illustrating examples of rectangular extraction methods. Where a filter function such as that shown in FIG. 25A is used, as a first operation, parts having identical values arranged in a horizontal direction may be merged to form rectangles, as shown in FIG. 25B. Afterward, as a second operation, rows having a same shape in a vertical direction may be merged to form new rectangles, as shown in FIG. 25C. Because the filter function is typically expressed in finer-grained cells than the examples here, such rectangular extraction may be performed on a computer. Also, the method of extracting rectangles is not limited thereto. For example, it may also be possible to extract rectangles as shown in FIG. 25D.

Also in Embodiment 6, the computer 12 may determine the far-field by using the far-field calculation method according to Embodiment 6 when a certain condition is satisfied, and may determine the far-field by using the far-field calculation method according to the comparative example when the certain condition is not satisfied. In addition, in Embodiment 6, the far-field calculation instruction may be executed by hardware to implement a user interface through which a user may select whether to determine the far-field by the far-field calculation method according to Embodiment 6 or by the far-field calculation method according to the comparative example.

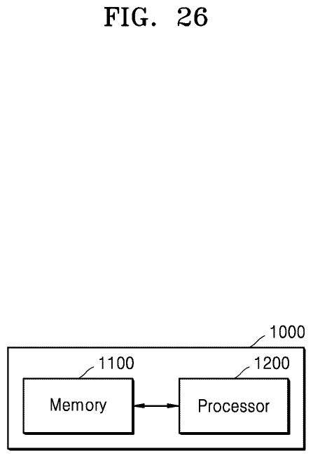

FIG. 26 is a block diagram of a system according to one or more embodiments.

As shown in FIG. 26, the system 1000 may include a memory 1100 and a processor 1200. However, the configuration shown in FIG. 26 is an example for implementing the embodiments, and other hardware and software configurations may be additionally included in the system 1000 as will be understood to one of ordinary skill in the art from the disclosure herein. According to one or more embodiments, the system 1000 may be implemented in the form of an electronic device.

The system 1000 according to one or more embodiments may be configured to perform operations such as determining, by a computer using an electromagnetic field analysis method, a near-field of each of a plurality of cells in a target structure, determining, by the computer using a filter function, a factor for each of the plurality of cells required for determining a far-field, and determining, by the computer using the near-field of each of the plurality of cells and the factors, a far-field of the target structure.

The memory 1100 may store commands or data related to at least one other component of the system 1000. Also, the memory 1100 may be accessed by the processor 1200, and reading/writing/modifying/deleting/updating of data may be performed by the processor 1200.

The term memory may include the memory 1100, a read-only memory (ROM) or a random access memory (RAM) in the processor 1200, or a memory card (e.g., a micro secure digital (SD) card or a memory stick) mounted in the system 1000. In addition, the memory 1100 may store programs and data for configuring various screens to be displayed on a display area of a display.

According to one or more embodiments, the memory 1100 may include a non-volatile memory capable of maintaining stored information even if power supply is interrupted, and a volatile memory requiring continuous power supply to maintain stored information. For example, the non-volatile memory may be implemented as at least one of one time programmable ROM (OTPROM), programmable ROM (PROM), erasable and programmable ROM (EPROM), electrically erasable and programmable ROM (EEPROM), mask ROM, or flash ROM, and the volatile memory may be implemented as at least one of dynamic RAM (DRAM), static RAM (SRAM), or synchronous dynamic RAM (SDRAM).

The processor 1200 may be electrically connected to the memory 1100 to control all operations and functions of the system 1000.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments (e.g., Embodiments 1-6 and other embodiments) provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

1. A method of determining a far-field, the method comprising:
determining, by a computer using an electromagnetic field analysis method, a near-field of each of a plurality of cells in a target structure;
determining, by the computer using a filter function, a factor for each of the plurality of cells required for determining a far-field of the target structure; and
determining, by the computer using the near-field of each of the plurality of cells and the factor for each of the plurality of cells, the far-field of the target structure.

2. The method of claim 1, wherein the determining of the factor for each of the plurality of cells comprises determining the factor for each of the plurality of cells using a transform function obtained using an analytic Fourier transform of the filter function.

3. The method of claim 1, wherein the determining of the factor for each of the plurality of cells comprises determining the factor for each of the plurality of cells using array data comprising a numerical Fourier transform of the filter function and an interpolation function.

4. The method of claim 1, wherein the plurality of cells comprise a plurality of first cells and at least one second cell located in an area between the plurality of first cells,
wherein the determining of the factor for each of the plurality of cells comprises determining, by the computer and using an interpolation coefficient multiplied by the filter function, a first factor for the plurality of first cells, and
wherein the determining of the far-field of the target structure comprises determining the far-field of the target structure based on the near-field of each of the plurality of first cells, the first factor, the near-field of the at least one second cell, and a second factor determined by linear approximation or higher-order approximation from the first factor.

5. The method of claim 1, wherein the plurality of cells comprise a first cell group and a second cell group having symmetry or anti-symmetry with respect to translation or inversion of the first cell group,
wherein the determining of the near-field of each of the plurality of cells comprises determining a first near-field of each of the plurality of cells in the first cell group, and
wherein the determining of the far-field of the target structure comprises determining the far-field of the target structure using near-fields of corresponding cells of the first cell group having symmetry or anti-symmetry with respect to the plurality of cells in the second cell group and factors of the second cell group.

6. The method of claim 1, wherein the determining of the factor for each of the plurality of cells comprises determining the factor for each of the plurality of cells by performing analytical calculation of a weighted geometric series.

7. The method of claim 1, wherein the plurality of cells comprise a defective cell,
wherein the determining of the near-field of each of the plurality of cells comprises determining, by the computer, a first near-field corresponding to a case where no defective cell is in the plurality of cells and a second near-field of the defective cell, and
wherein the determining of the far-field of the target structure comprises:
determining, by the computer, a first far-field by using the first near-field; and
determining the far-field of the target structure by adding a second far-field, which is an amount of change in the far-field due to the second near-field, to the first far-field.

8. The method of claim 1, wherein the plurality of cells comprise a rectangular area comprising cells in which values of the filter function are not 0 and are equal to each other in a rectangular shape, and
wherein the determining of the factor for each of the plurality of cells comprises determining the factor for each of the plurality of cells by using an exact solution of a geometric series for the rectangular area.

9. The method of claim 1, wherein the determining of the far-field of the target structure comprises determining a far-field distribution from which noise due to discontinuity of the filter function is removed by using a transform function obtained by an analytic Fourier transform of the filter function.

10. The method of claim 1, wherein the determining of the factor for each of the plurality of cells comprises receiving, by the computer, as an input, rectangular areas comprising cells in which values of the filter function are not 0 and are equal to each other in a rectangular shape and determining the factor for each of the plurality of cells using an exact solution of a geometric series for each of the rectangular areas.

11. An electronic device comprising:
memory storing instructions, and
a processor,
wherein the instructions, when executed by the processor, cause the electronic device to:
determine, by using an electromagnetic field analysis method, a near-field of each of a plurality of cells in a target structure;
determine, by using a filter function, a factor for each of the plurality of cells required for determining a far-field of the target structure; and
determine, based on the near-field of each of the plurality of cells and the factor for each of the plurality of cells, the far-field of the target structure.

12. The electronic device of claim 11, wherein the instructions, when executed by the processor, cause the electronic device to determine the factor for each of the plurality of cells by using a transform function obtained using an analytic Fourier transform of the filter function.

13. The electronic device of claim 11, wherein the instructions, when executed by the processor, cause the electronic device to determine the factor for each of the plurality of cells by using array data comprising a numerical Fourier transform of the filter function and an interpolation function.

14. The electronic device of claim 11, wherein the plurality of cells comprise a plurality of first cells, and at least one second cell located in an area between the plurality of first cells,
wherein the instructions, when executed by the processor, cause the electronic device to determine the factor for each of the plurality of cells by determining, using an interpolation coefficient multiplied by the filter function, a first factor for the plurality of first cells, and
wherein the instructions, when executed by the processor, cause the electronic device to determine the far-field of the target structure based on the near-field of each of the plurality of first cells, the first factor, the near-field of the at least one second cell, and a second factor determined by linear approximation or higher-order approximation from the first factor.

15. The electronic device of claim 11, wherein the plurality of cells comprise a first cell group and a second cell group having symmetry or anti-symmetry with respect to translation or inversion of the first cell group,
wherein the instructions, when executed by the processor, cause the electronic device to determine the near-field of each of the plurality of cells by determining a near-field of each of the plurality of cells in the first cell group, and
wherein the instructions, when executed by the processor, cause the electronic device to determine of the far-field of the target structure by using near-fields of corresponding cells of the first cell group having symmetry or anti-symmetry with respect to the plurality of cells in the second cell group and factors of the second cell group.

16. The electronic device of claim 11, wherein the instructions, when executed by the processor, cause the electronic device to determine the factor for each of the plurality of cells by performing analytical calculation of a weighted geometric series.

17. The electronic device of claim 11, wherein the plurality of cells comprise a defective cell,
wherein the instructions, when executed by the processor, cause the electronic device to determine the near-field of each of the plurality of cells by determining a first near-field corresponding to a case where no defective cell is in the plurality of cells and a second near-field of the defective cell, and
wherein the instructions, when executed by the processor, cause the electronic device to determine the far-field of the target structure by:
determining a first far-field by using the first near-field; and
determining the far-field of the target structure by adding a second far-field, which is an amount of change in the far-field due to the second near-field of the defective cell, to the first far-field.

18. The electronic device of claim 11, wherein the plurality of cells further comprise a rectangular area comprising cells in which values of the filter function are not 0 and are equal to each other in a rectangular shape, and
wherein the instructions, when executed by the processor, cause the electronic device to determine the factor for each of the plurality of cells by using an exact solution of a geometric series for the rectangular area.

19. The electronic device of claim 11, wherein the instructions, when executed by the processor, cause the electronic device to determine the far-field of the target structure by determining a far-field distribution, from which noise due to discontinuity of the filter function is removed, by using a transform function obtained by an analytic Fourier transform of the filter function.

20. (canceled)

21. A non-transitory computer-readable storage medium storing instructions that, when executed by at least one processor, cause the at least one processor to:
determine, by using an electromagnetic field analysis method, a near-field of each of a plurality of cells in a target structure;
determine, by using a filter function, a factor for each of the plurality of cells required for determining a far-field of the target structure; and
determine, based on the near-field of each of the plurality of cells and the factor for each of the plurality of cells, the far-field of the target structure.
